(19) United States
(12) Patent Application Publication
(10) Pub. No.: US 2025/0157896 A1
(43) Pub. Date: May 15, 2025

(54) INTEGRATED CIRCUIT DEVICE

(71) Applicant: SAMSUNG ELECTRONICS CO., LTD., Suwon-si (KR)

(72) Inventors: Sangjine PARK, Suwon-si (KR); Youngjun KIM, Suwon-si (KR); Taesun KIM, Suwon-si (KR)

(73) Assignee: SAMSUNG ELECTRONICS CO., LTD., Suwon-si (KR)

(21) Appl. No.: 18/824,553

(22) Filed: Sep. 4, 2024

(30) Foreign Application Priority Data
Nov. 14, 2023 (KR) 10-2023-0157688

(51) Int. Cl. H01L 23/495; H01L 23/498; H01L 27/092

(52) U.S. Cl. CPC H01L 23/49562; H01L 23/49548; H01L 23/49872; H10D 84/853

(57) ABSTRACT

An integrated circuit device includes: a substrate including a backside surface; fin-type active regions protruding from the substrate such as to define a trench region on the substrate; a device isolation layer covering, in the trench region, a side wall of each of the fin-type active regions; a via power rail vertically extending through the device isolation layer between the fin-type active regions; and a backside power rail vertically extending through the substrate and connected to one end of the via power rail, wherein the via power rail includes a first portion connected to the backside power rail and a second portion on the first portion, and wherein two side walls of the first portion each include an inclined surface that is inclined such as to come closer to the pair of fin-type active regions as the two side walls approach the backside power rail.

### CROSS-REFERENCE TO RELATED APPLICATION

This application claims priority under 35 U.S.C. § 119 to Korean Patent Application No. 10-2023-0157688, filed on Nov. 14, 2023, in the Korean Intellectual Property Office, the disclosure of which is incorporated by reference herein in its entirety.

### BACKGROUND

### 1. Technical Field

Embodiments of the present disclosure relate to an integrated circuit device, and particularly, to an integrated circuit device including a power rail.

### 2. Brief Description of Related Art

As electronic devices require miniaturization, multifunction, and high-performance, integrated circuit devices are required to have high-capacity and to be highly integrated. Accordingly, wiring structures need to be efficiently designed to achieve high integration while increasing functions and operating speed required by the integrated circuit devices.

### SUMMARY

According to embodiments of the present disclosure, an integrated circuit device with improved electrical characteristics and reliability is provided.

Aspects achieved by embodiments of the present disclosure are not limited to the objects described above, and other objects may be clearly understood by those skilled in the art from descriptions below.

According to embodiments of the present disclosure, an integrated circuit device is provided and includes: a substrate including a backside surface; a pair of fin-type active regions protruding from the substrate such as to define a trench region on the substrate on a side of the substrate that is opposite of the backside surface; a device isolation layer covering, in the trench region, a side wall of each of the pair of fin-type active regions; a via power rail vertically extending through the device isolation layer between the pair of fin-type active regions; and a backside power rail vertically extending through the substrate from the backside surface of the substrate and connected to one end of the via power rail, wherein the via power rail includes a first portion connected to the backside power rail and a second portion on the first portion, and wherein two side walls of the first portion, that are opposite of each other and respectively face the pair of fin-type active regions, each include an inclined surface that is inclined such as to come closer to the pair of fin-type active regions as the two side walls approach the backside power rail.

According to embodiments of the present disclosure, an integrated circuit device is provided and includes: a substrate including a backside surface; a pair of fin-type active regions protruding from the substrate such as to define a trench region on the substrate on a side of the substrate that is opposite of the backside surface; a pair of source/drain regions respectively over the pair of fin-type active regions; a device isolation layer covering, in the trench region, a side wall of each of the pair of fin-type active regions; a via power rail between the pair of fin-type active regions and between the pair of source/drain regions and vertically extending through the device isolation layer; and a backside power rail vertically extending through the substrate from the backside surface of the substrate and connected to one end of the via power rail, wherein the via power rail includes a first portion connected to the backside power rail and a second portion on the first portion, and wherein two side walls of the first portion respectively face the pair of fin-type active regions and are curved surfaces.

According to embodiments of the present disclosure, an integrated circuit device is provided and includes: a substrate including a backside surface; a fin-type active region protruding from the substrate, on a side of the substrate that is opposite of the backside surface, such as to define part of a trench region on the substrate, the fin-type active region elongated in a first horizontal direction; at least one nanosheet on the fin-type active region and separated vertically from an upper surface of the fin-type active region; a gate line surrounding the at least one nanosheet on the fin-type active region, the gate line elongated in a second horizontal direction intersecting the first horizontal direction; a source/drain region adjacent to the gate line and on the fin-type active region, the source/drain region connected to the at least one nanosheet; a device isolation layer on the substrate and covering, in the trench region, a part of a side wall of the fin-type active region; a via power rail separated horizontally from each of the fin-type active region, the source/drain region, and the gate line and vertically extending through the device isolation layer and the gate line; and a backside power rail vertically extending through the substrate from the backside surface of the substrate and connected to one end of the via power rail, wherein the via power rail includes a first portion connected to the backside power rail and a second portion on the first portion, wherein the first portion includes at least a portion having a width in the second horizontal direction that increases toward the backside surface, and wherein the second portion has a width in the second horizontal direction that decreases toward the backside surface.

### BRIEF DESCRIPTION OF THE DRAWINGS

Embodiments will be more clearly understood from the following detailed description taken in conjunction with the accompanying drawings in which:

FIG. 1 is a plan layout view illustrating a cell block of an integrated circuit device according to an embodiment;

FIG. 2 is a plan layout view illustrating an integrated circuit device according to an embodiment;

FIG. 3A is a cross-sectional view taken along line X1-X1′ of FIG. 2;

FIG. 3B is a cross-sectional view taken along line Y1-Y1′ of FIG. 2;

FIG. 3C is a cross-sectional view taken along line Y2-Y2′ of FIG. 2;

FIG. 3D is an enlarged cross-sectional view of a portion “EX2” of FIG. 3B;

FIG. 4 is a view illustrating an integrated circuit device according to another embodiment;

FIG. 5A is a view illustrating an integrated circuit device according to another embodiment;

FIG. 5B is a view illustrating an integrated circuit device according to another embodiment;

FIG. 6 is a view illustrating an integrated circuit device according to another embodiment;

FIG. 7 is a view illustrating an integrated circuit device according to another embodiment;

FIG. 8 is a view illustrating an integrated circuit device according to another embodiment;

FIG. 9 is a view illustrating an integrated circuit device according to another embodiment; and

FIGS. 10, 11, 12A, 12B, 12C, 13, 14A, 14B, 14C, 15, 16, 17, 18A, 18B, 18C, 19A, 19B, 19C, 20A, 20B, 21A, 21B, 22A, 22B, 23A, 23B, 23C, 24A, 24B, 25A, 25B, 26A, 26B and 26C are views illustrating in process sequence a method of manufacturing an integrated circuit device, according to an embodiment; and

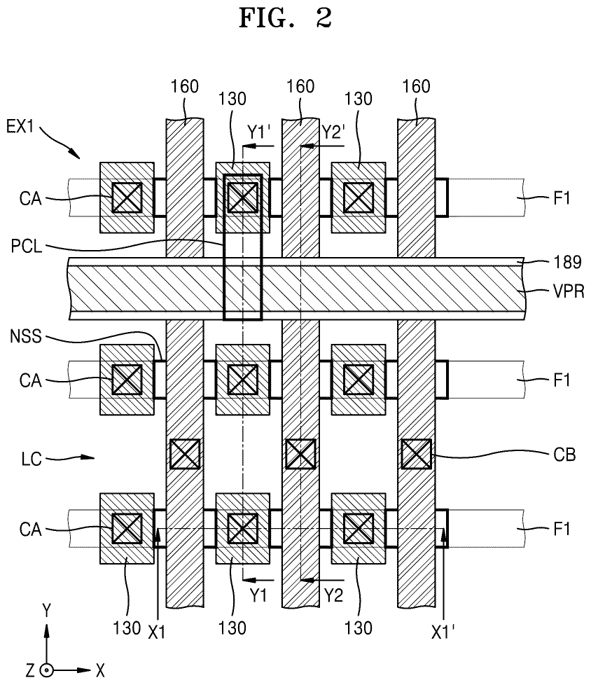

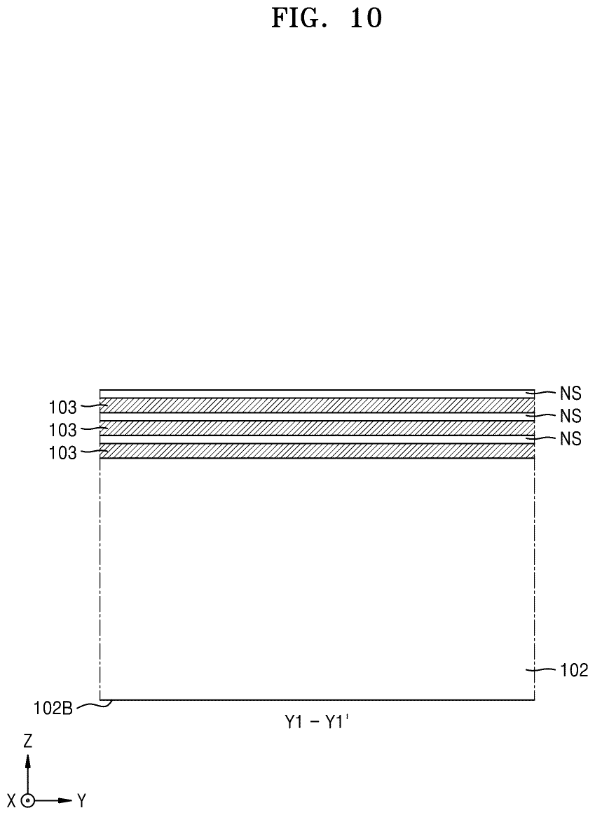

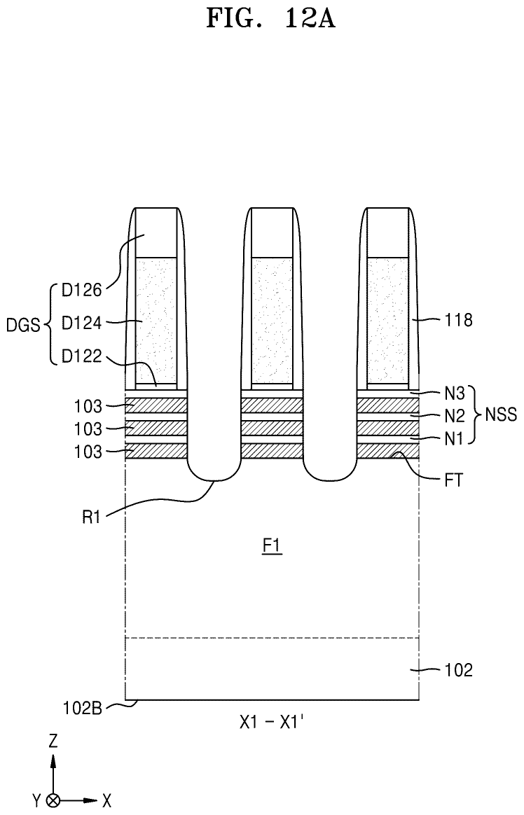

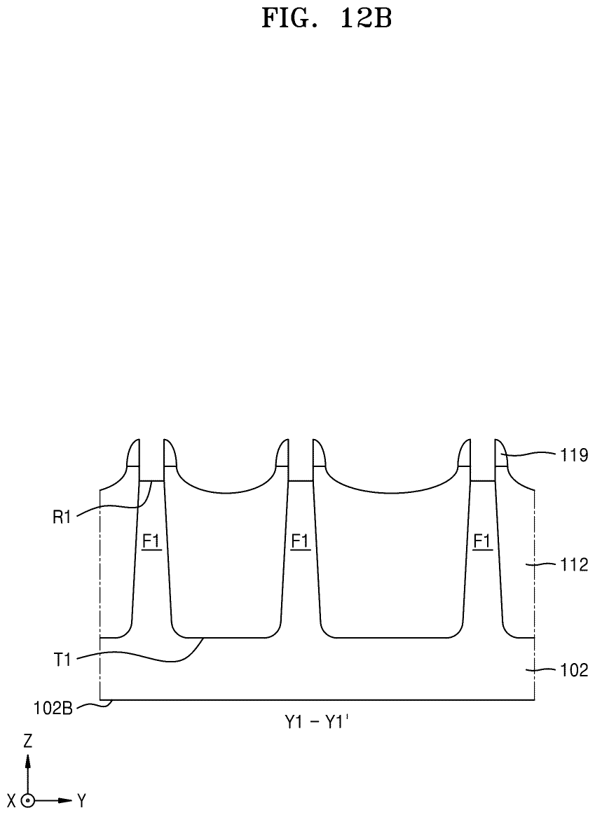

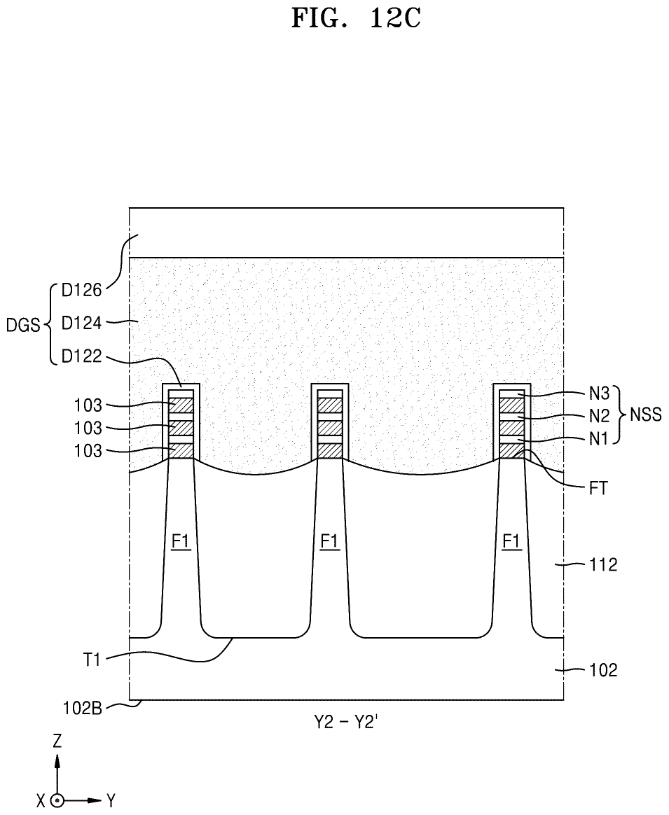

For example, FIGS. 10, 11, 12B, 13, 14B, 18B, 19B, 20A, 21A, 22A, 23A, 24A, 25A, and 26B are cross-sectional views illustrating cross-sectional structures according to a process sequence of a portion corresponding to a cross-section taken along line Y1-Y1′ of FIG. 2; FIGS. 12A, 14A, 15, 16, 17, 18A, 19A, and 26A are cross-sectional views illustrating cross-sectional structures according to a process sequence of a portion corresponding to a cross-section taken along line X1-X1′ of FIG. 2; and FIGS. 12C, 14C, 18C, 19C, 20B, 21B, 22B, 23B, 24B, 25B, and 26C are cross-sectional views illustrating cross-sectional structures according to a process sequence of a portion corresponding to a cross-section taken along line Y2-Y2′ of FIG. 2.

### DETAILED DESCRIPTION

Embodiments described herein are non-limiting example embodiments, and thus, the present disclosure is not limited thereto.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claims without departing from the teachings of the present disclosure.

It will be understood that when an element or layer is referred to as being “over,” “on,” “below,” or “connected to” another element or layer, it can be directly over, on, below, or connected to the other element or layer or intervening elements or layers may be present. In contrast, when an element is referred to as being “directly over,” “directly on,” “directly below,” or “directly connected to” another element or layer, there are no intervening elements or layers present.

Hereinafter, non-limiting example embodiments of the present disclosure will be described in detail with reference to the accompanying drawings. The same reference numerals are used for the same components in the drawings, and redundant descriptions thereof may be omitted.

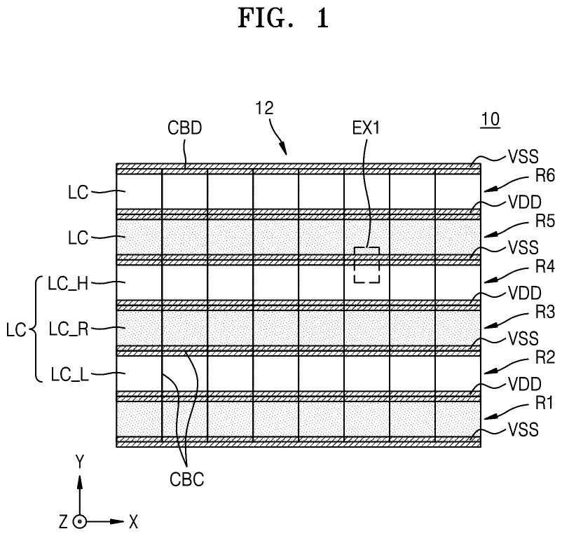

FIG. 1 is a plan layout view illustrating a cell block 12 of an integrated circuit device 10 according to embodiments.

Referring to FIG. 1, the cell block 12 of the integrated circuit device 10 may include a plurality of logic cells LC including circuit patterns for configuring various circuits. The plurality of logic cells LC may be arranged in a matrix in the cell block 12 in a first horizontal direction X and a second horizontal direction Y.

The plurality of logic cells LC may include a circuit pattern of a layout designed according to a place and route (PnR) technique to perform at least one logic function. The plurality of logic cells LC may each have a function of performing various logic functions. In embodiments, the plurality of logic cells LC may include a plurality of standard cells. In embodiments, at least some of the plurality of logic cells LC may perform the same logic function. In other embodiments, at least some of the plurality of logic cells LC may perform different logic functions.

The plurality of logic cells LC may include various types of logic cells including a plurality of circuit elements. For example, the plurality of logic cells LC may each be comprised of an AND gate, a NAND gate, an OR gate, a NOR gate, an exclusive OR (XOR) gate, an exclusive NOR (XNOR) XOR, an inverter (INV), an adder (ADD), a buffer (BUF), a delay (DLY), a filter (FIL), a multiplexer (MXT/MXIT), OR/AND/INVERTER (OAI), an AND/OR (AO) gate, AND/OR/INVERTER (AOI), a D flip-flop, a reset flip-flop, a master-slave flip-flop, a latch, or one of combinations thereof but are not limited thereto.

In the cell block 12, at least some of the plurality of logic cells LC in one row (e.g., row R1, row R2, row R3, row R4, row R5, or row R6) in the first horizontal direction X may have the same width. Also, at least some of the plurality of logic cells LC in one row (e.g., row R1, row R2, row R3, row R4, row R5, or row R6) may have the same height. However, embodiments of the present disclosure are not limited to what is illustrated in FIG. 1, and at least some of the plurality of logic cells LC in one row (e.g., row R1, row R2, row R3, row R4, row R5, or row R6) may also have different widths and heights from each other.

An area of each of the plurality of logic cells LC included in the cell block 12 of the integrated circuit device 10 may be limited by a cell boundary CBD. A cell upper contact portion CBC, in which respective ones of the cell boundary CBD are connected to each other, may be between two logic cells LC adjacent to each other in the first horizontal direction X or the second horizontal direction Y among the plurality of logic cells LC.

In embodiments, two logic cells LC adjacent to each other in the first horizontal direction among the plurality of logic cells LC in one row (e.g., row R1, row R2, row R3, row R4, row R5, or row R6) may be connected to each other at the cell upper contact portion CBC without any separation distance therebetween. In other embodiments, two logic cells LC adjacent to each other in the first horizontal direction X among the plurality of logic cells LC in one row (e.g., row R1, row R2, row R3, row R4, row R5, or row R6) may be separated from each other with a predetermined separation distance therebetween.

In embodiments, two logic cells LC adjacent to each other among the plurality of logic cells LC in one row (e.g., row R1, row R2, row R3, row R4, row R5, or row R6) may perform the same function. In this case, the two adjacent logic cells LC may have the same structure. In other embodiments, two logic cells LC adjacent to each other among the plurality of logic cells LC in one row (e.g., row R1, row R2, row R3, row R4, row R5, or row R6) may have different functions from each other.

In embodiments, one logic cell LC selected from among the plurality of logic cells LC included in the cell block 12 of the integrated circuit device 10 and another logic cell LC adjacent to the selected logic cell LC in the second horizontal direction Y (refer to FIG. 1) may have a symmetrical structure with respect to the cell upper contact portion CBC therebetween. For example, a reference logic cell LC_R in the row R3 (e.g., a third row) and a lower logic cell LC_R in the row R2 (e.g., a second row) may have a symmetrical structure with respect to the cell upper contact portion CBC therebetween Also, the reference logic cell LC_R in the row R3 and an upper logic cell LC_R in the row R2 may have a symmetrical structure with respect to the cell upper contact portion CBC therebetween.

Although FIG. 1 illustrates the cell block 12 including six rows, this is only an example, and the cell block 12 may include a various number of rows, and each row may include a various number of logic cells.

One line selected from a plurality of ground lines VSS and a plurality of power lines VDD may be between two rows among the plurality of rows (e.g., row R1, row R2, row R3, row R4, row R5, and row R6) each including a plurality of logic cells LC arranged in a row in the first horizontal direction X. The plurality of ground lines VSS and the plurality of power lines VDD may each extend in the first horizontal direction X, be separated from each other in the second horizontal direction Y, and be arranged alternately. Accordingly, the plurality of ground lines VSS and the plurality of power lines VDD may be arranged to overlap the cell boundary CBD in the second horizontal direction Y of the respective logic cells LC.

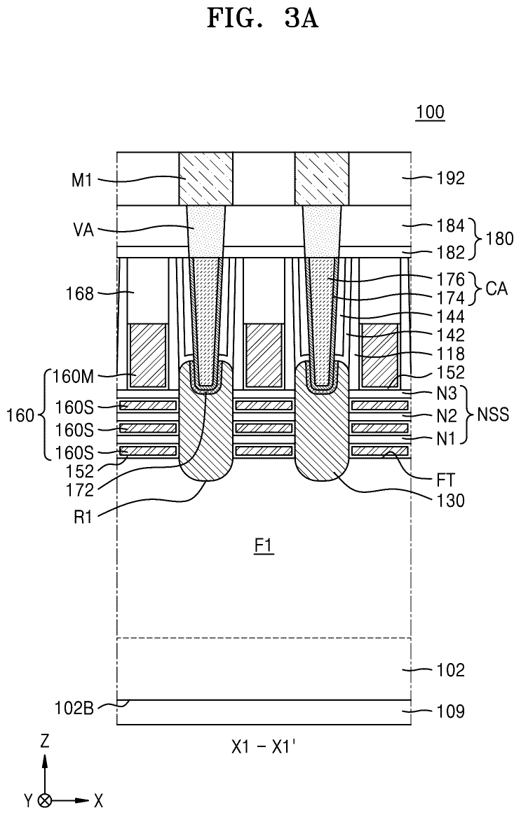

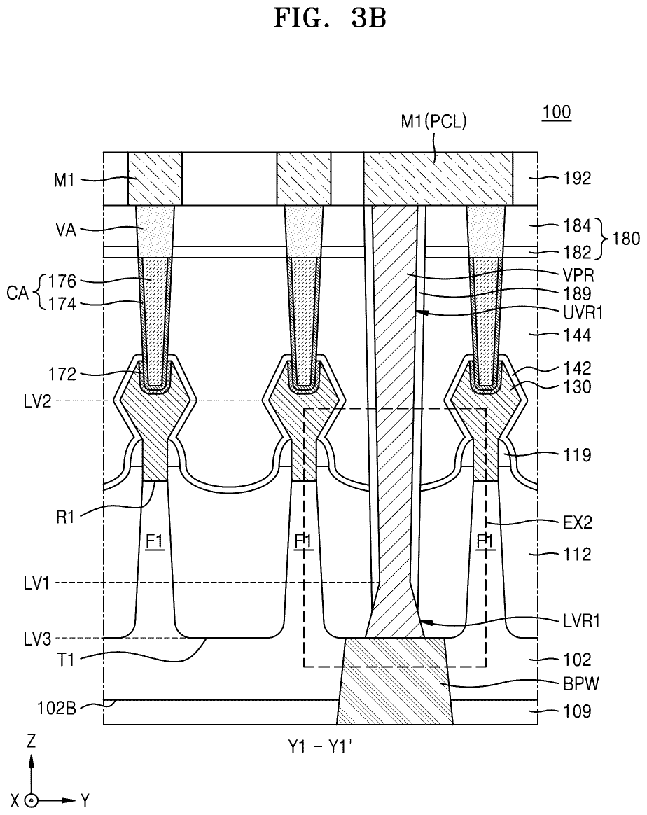

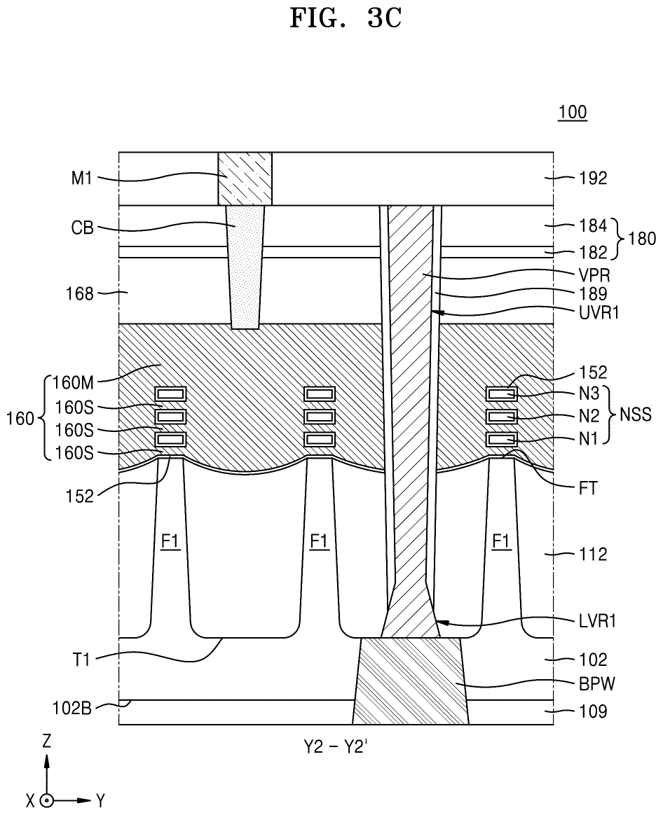

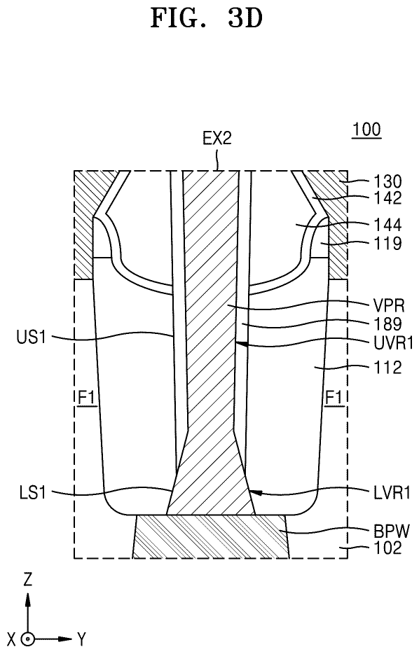

FIG. 2 is a plan layout view illustrating an integrated circuit device 100 according to embodiments. FIG. 3A is a cross-sectional view taken along line X1-X1′ of FIG. 2.

FIG. 3B is a cross-sectional view taken along line Y1-Y1′ of FIG. 2. FIG. 3C is a cross-sectional view taken along line Y2-Y2′ of FIG. 2. FIG. 3D is an enlarged cross-sectional view illustrating a portion “EX2” of FIG. 3B. FIGS. 2, 3A, 3B, 3C, and 3D illustrate the integrated circuit device 100 including a field effect transistor having a gate-all-around structure including an active region of a nanowire shape or a nanosheet shape and a gate surrounding the active region. The integrated circuit device 100 may form part of the plurality of logic cells LC illustrated in FIG. 1.

Referring to FIGS. 2, 3A, 3B, 3C, and 3D, the integrated circuit device 100 may include two logic cells LC adjacent to each other in the second horizontal direction Y with a via power rail VPR therebetween. The via power rail VPR may form the ground line VSS illustrated in FIG. 1.

The integrated circuit device 100 may include a substrate 102 having a backside surface 102B and a plurality of fin-type active regions F1 protruding from the substrate 102 on a side of the substrate 102, opposite of the backside surface 102B, to define a plurality of trench regions T1. The plurality of fin-type active regions F1 may be elongated in the first horizontal direction X on the substrate 102 and may extend parallel to each other.

The substrate 102 may include a semiconductor, such as Si or Ge, or a compound semiconductor, such as SiGe, SiC, GaAs, InAs, InGaAs, or InP. Terms “SiGe”, “SiC”, “GaAs”, “InAs”, “InGaAs”, and “InP” used in the present disclosure may each refer to a material composed of elements included in each term and are not chemical formulas that represent a stoichiometric relationship. The substrate 102 may include a conductive region, for example, a well doped with an impurity, or a structure doped with an impurity.

A device isolation layer 112 may be in the trench region T1 defining the plurality of fin-type active regions F1. The device isolation layer 112 covers part of a side wall of each of the plurality of fin-type active regions F1 in the plurality of trench regions T1 and may be separated from the substrate 102 in the vertical direction Z. The device isolation layer 112 may include a silicon oxide film.

As illustrated in FIGS. 3B and 3C, the via power rail VPR may extend in the vertical direction Z between a pair of adjacent fin-type active regions F1 selected from among the plurality of fin-type active regions Fl and between a pair of source/drain regions 130 on the pair of fin-type active regions F1.

In embodiments, the via power rail VPR may include a first metal wiring layer. The first metal wiring layer may include a low resistance metal, for example, Ru, Co, W, Mo, Cu, Rh, Ir, Ti, or a combination thereof. In embodiments, the via power rail VPR may include a single metal wiring layer, and the metal wiring layer may include any one selected from Ru, Co, W, Mo, Cu, Rh, Ir, and Ti. In other embodiments, the via power rail VPR may include a plurality of metal wiring layers, and the plurality of metal wiring layers may each include any one selected from Ru, Co, W, Mo, Cu, Rh, Ir, and Ti.

The via power rail VPR may include a first portion LVR1 connected to a backside power rail BPW and a second portion UVR1 on the first portion LVR1. For example, a part of a lower portion of the via power rail VPR may be defined as the first portion LVR1, and the other part of the lower portion may be defined as the second portion UVR1.

As illustrated in FIGS. 3B, 3C, and 3D, the first portion LVR1 may have a shape of which width in the second horizontal direction Y uniformly increases from the top toward the bottom, while the second portion UVR1 may have a shape of which width in the second horizontal direction Y uniformly decreases from the top toward the bottom. For example, the first portion LVR1 may have a shape of which width in the second horizontal direction Y uniformly increases toward the backside surface 102B of the substrate 102, while the second portion UVR1 may have a shape of which width in the second horizontal direction Y uniformly decreases toward the backside surface 102B of the substrate 102. A cross-sectional area of the first portion LVR1 may increase from the top toward the bottom, and a cross-sectional area of the second portion UVR1 may decrease from the top toward the bottom. In addition, a cross-sectional area of the first portion LVR1 may increase toward the backside surface 102B, and a cross-sectional area of the second portion UVR1 may decrease toward the backside surface 102B.

Because a pair of fin-type active regions F1 are separated from the first portion LVR1, the greatest width of the first portion LVR1 may be less than a separation distance between the pair of fin-type active regions F1. In embodiments, the smallest width of the first portion LVR1 may be equal to the smallest width of the second portion UVR1.

In embodiments, when the via power rail VPR is cut in the second horizontal direction Y, the first portion LVR1 may have a trapezoid shape, that is, a trapezoidal cross-section having a lower part wider than an upper part, and the second portion UVR1 may have an inverse trapezoid shape, that is, a trapezoidal cross-section having an upper part wider than a lower part. For example, the first portion LVR1 may include two side walls LS1 that are inclined surfaces, and the second portion UVR1 may have two side walls US1 that are inclined surfaces in a direction different from the direction in which two side walls LS1 of the first portion LVR1 are inclined. For example, both side walls LS1 of the first portion LVR1 may be side walls of a hexahedron having a trapezoidal cross-section, and both side walls US1 of the second portion UVR1 may be side walls of a hexahedron having an inverse trapezoidal cross-section. In embodiments, both side walls LS1 of the first portion LVR1 may be connected to lower ends of both side walls US1 of the second portion UVR1.

In embodiments, a vertical level LV1 of where the first portion LVR1 meets the second portion UVR1 may be between a vertical level LV2 of a portion closest to the via power rail VPR in the pair of source/drain regions 130 adjacent to the via power rail VPR and a vertical level LV3 of an upper surface of the backside power rail BPW. The term “vertical level” used herein means a distance in the vertical direction Z or −Z from the backside surface 102B of the substrate 102.

Part of a side wall of the via power rail VPR may be covered by an insulating spacer 189. For example, an insulating spacer 189 may cover part of a side wall of the first portion LVR1 of the via power rail VPR and cover the entire side wall of the second portion UVR1 of the via power rail VPR. The insulating spacer 189 may conformally extend along a side wall of the second portion UVR1 to be connected to the side walls LS1 of the first portion LVR1. In this case, a portion of the insulating spacer 189 which is connected to the side walls LS1 of the first portion LVR1 may have a sharp shape toward the backside surface 102B. In embodiments, the insulating spacer 189 may include a silicon oxide film, a silicon oxynitride film, or a combination thereof.

The entire side wall of the second portion UVR1 of the via power rail VPR may be covered by the insulating spacer 189, but some of the side wall of the first portion LVR1 may not be covered by the insulating spacer 189. For example, an upper part of the first portion LVR1 may be separated from the device isolation layer 112 with the insulating spacer 189 therebetween, but the lower part of the first portion LVR1 may be directly connected to the device isolation layer 112.

The backside surface 102B of the substrate 102 may be covered by a backside insulating layer 109. The backside insulating layer 109 may include a silicon oxide film, a silicon nitride film, a silicon carbide film, a low dielectric film, or a combination thereof. The low dielectric film may include fluorine-doped silicon oxide, organosilicate glass, carbon-doped oxide, porous silicon oxide, porous organosilicate glass, spin-on organic polymeric dielectric, spin-on silicon based polymeric dielectric, or a combination thereof but is not limited thereto.

As illustrated in FIGS. 3B, 3C, and 3D, a backside power rail BPW extending through the backside insulating layer 109 and the substrate 102 in the vertical direction Z may be provided. The backside power rail BPW may pass through the substrate 102 in the vertical direction Z from the backside surface 102B of the substrate 102 to be connected to one end of the via power rail VPR.

In embodiments, the backside power rail BPW may include a second metal wiring layer. The second metal wiring layer may include a low-resistance metal, for example, Ru, Co, W, Mo, Cu, Rh, Ir, Ti, or a combination thereof. In other embodiments, the backside power rail BPW may include a second metal wiring layer and a conductive barrier layer surrounding the second metal wiring layer. The conductive barrier layer may include Ti, TiN, Ta, TaN, or a combination thereof.

In embodiments, the backside power rail BPW may cover the entire lower surface of the via power rail VPR and a lower surface of the device isolation layer 112 which is adjacent to the via power rail VPR. In other embodiments, the backside power rail BPW may cover all or part of the lower surface of the via power rail VPR and may not cover the lower surface of the device isolation layer 112 which is adjacent to the via power rail VPR.

As illustrated in FIGS. 2, 3A, and 3C, a plurality of gate lines 160 may be arranged on the plurality of fin-type active regions F1. The plurality of gate lines 160 may be elongated in the second horizontal direction Y. A plurality of nanosheet stacks NSS may be arranged on an upper surface FT of each of the plurality of fin-type active regions F1 in areas where the plurality of fin-type active regions F1 intersect the plurality of gate lines 160. The plurality of nanosheet stacks NSS may each include at least one nanosheet facing the upper surface FT at a position separated from the upper surface FT of the fin-type active region F1 in the vertical direction Z. The term “nanosheet” used herein refers to a conductive structure having a cross-section that is substantially perpendicular to a direction in which a current flows. The nanosheet may include a nanowire.

As illustrated in FIGS. 3A and 3C, the plurality of nanosheet stacks NSS may each include a first nanosheet N1, a second nanosheet N2, and a third nanosheet N3 that overlap each other on the fin-type active region F1 in the vertical direction Z. The first nanosheet N1, the second nanosheet N2, and the third nanosheet N3 may have different vertical distances in the vertical direction Z from the upper surface FT of the fin-type active region F1. The plurality of gate lines 160 may surround the first nanosheet N1, the second nanosheet N2, and the third nanosheet N3 that are included in the nanosheet stack NSS and overlap each other in the vertical direction Z.

Although FIG. 2 illustrates a case where a plan shape of the nanosheet stack NSS is approximately square, embodiments of the present disclosure are not limited thereto. The nanosheet stacks NSS may have various plan shapes depending on plan shapes of the fin-type active regions F1 and the gate lines 160. The present embodiment provides a structure in which the plurality of nanosheet stacks (NSS) and the plurality of gate lines 160 are arranged on one of the fin-type active regions F1 and the plurality of nanosheet stacks NSS are arranged on one of the fin-type active regions F1 in a row in the first horizontal direction X. However, the number of nanosheet stacks NSS arranged on one of the fin-type active regiosn F1 and the number of gate lines 160 arranged on one of the fin-type active regions F1 are not limited.

The first nanosheet N1, the second nanosheet N2, and the third nanosheet N3 included in the nanosheet stack NSS may each function as a channel region. In embodiments, the first nanosheet N1, the second nanosheet N2, and the third nanosheet N3 may each have a thickness selected from a range of about 4 nm to about 6 nm but is not limited thereto. Here, the thickness of each of the first nanosheet N1, the second nanosheet N2, and the third nanosheet N3 refers to a size in the vertical direction Z. In embodiments, the first nanosheet N1, the second nanosheet N2, and the third nanosheet N3 may have substantially the same thickness in the vertical direction Z. In other embodiments, the first nanosheet N1, the second nanosheet N2, and the third nanosheet N3 may have different thicknesses from each other in the vertical direction Z. In embodiments, the first nanosheet N1, the second nanosheet N2, and the third nanosheet N3 included in the nanosheet stack (NSS) may each include a Si layer, a SiGe layer, or a combination thereof.

As illustrated in FIG. 3A, the first nanosheet N1, the second nanosheet N2, and the third nanosheet N3 included in one nanosheet stack NSS may have sizes equal or similar to each other. In other embodiments, the first nanosheet N1, the second nanosheet N2, and the third nanosheet N3 included in one nanosheet stack NSS may have partially different sizes in the first horizontal direction X. Although the present embodiment provides a case where the plurality of nanosheet stacks NSS each have three nanosheets, embodiments of the present disclosure are not limited thereto. For example, the nanosheet stack NSS may include at least one nanosheet, and the number of nanosheets included in the nanosheet stack NSS is not limited.

As illustrated in FIGS. 3A and 3C, the plurality of gate lines 160 may each include a main gate portion 160M and a plurality of sub-gate portions 160S. The main gate portion 160M covers an upper surface of the nanosheet stack NSS and may be elongated in the second horizontal direction Y. The plurality of sub-gate portions 160S may be integrally connected to the main gate portion 160M and may each be between the first nanosheet N1, the second nanosheet N2, and the third nanosheet N3 and may each be between the first nanosheet N1 and at least one of the fin-type active regions F1. In the vertical direction Z, a thickness of each of the plurality of sub-gate portions 160S may be less than a thickness of the main gate portion 160M.

As illustrated in FIGS. 3A and 3B, a plurality of active region recesses R1 may be formed on the fin-type active regions F1. A vertical level of a lowermost surface of each of the plurality of active region recesses R1 may be lower than a vertical level of the upper surface FT of the fin-type active regions F1.

As illustrated in FIGS. 3A and 3B, a plurality of source/drain regions 130 may be respectively in the plurality of active region recesses R1. The plurality of source/drain regions 130 may each be adjacent to at least one from among the plurality of gate lines 160. The plurality of source/drain regions 130 may each have surfaces facing the first nanosheet N1, the second nanosheet N2, and the third nanosheet N3 included in the adjacent nanosheet stack NSS. The plurality of source/drain regions 130 may each be connected to the first nanosheet N1, the second nanosheet N2, and the third nanosheet N3 included in the adjacent nanosheet stack NSS.

The plurality of gate lines 160 may each include metal, metal nitride, metal carbide, or a combination thereof. The metal may be selected from Ti, W, Ru, Nb, Mo, Hf, Ni, Co, Pt, Yb, Tb, Dy, Er, and Pd. The metal nitride may be selected from TiN and TaN. The metal carbide may be TiAlC. However, a material forming each of the plurality of gate lines 160 is not limited thereto.

A gate dielectric layer 152 may be between the nanosheet stack NSS and the gate lines 160. In embodiments, the gate dielectric layer 152 may have a structure in which an interface dielectric layer and a high-k dielectric layer are stacked. The interface dielectric layer may include a low dielectric material layer with a dielectric constant of about 9 or less, for example, a silicon oxide film, a silicon oxynitride film, or a combination thereof. In embodiments, the interface dielectric layer may be omitted. The high-k dielectric layer may include a material with a higher dielectric constant than a dielectric constant of a silicon oxide film. For example, the high-k dielectric layer may have a dielectric constant of about 10 to about 25. The high-k dielectric layer may include hafnium oxide but is not limited thereto.

As illustrated in FIGS. 3A and 3C, an upper surface of each of the gate dielectric layer 152 and the gate lines 160 may be covered by a capping insulating pattern 168. The capping insulating pattern 168 may include a silicon nitride film or a silicon oxide film.

Both side walls of each of at least one of the gate lines 160 (e.g., the main gate portion 160M) and the capping insulating pattern 168 may be covered by an outer insulating spacer 118. The outer insulating spacer 118 may cover both side walls of the main gate portion 160M on an upper surface of each of the plurality of nanosheet stacks NSS. The outer insulating spacer 118 may be separated from the at least one of the gate lines 160 with the gate dielectric layer 152 therebetween.

As illustrated in FIG. 3B, a plurality of recess side insulating spacers 119 may be on an upper surface of the device isolation layer 112 to cover side walls of the plurality of source/drain regions 130. In embodiments, the plurality of recess side insulating spacers 119 may each be integrally connected to at least one of the outer insulating spacers 118 adjacent thereto.

The plurality of outer insulating spacers 118 and the plurality of recess side insulating spacers 119 may each include silicon nitride, silicon oxide, SiCN, SiBN, SiON, SiOCN, SiBCN, SiOC, or a combination thereof. The term “SiCN”, “SiBN”, “SiON”, “SiOCN”, “SiBCN”, and “SiOC” used herein each refer to a material composed of an element included in each term, and are not chemical formulas that represent a stoichiometric relationship.

A metal silicide layer 172 may be formed on an upper surface of each of the plurality of source/drain regions 130. The metal silicide layer 172 may include a metal made of Ti, W, Ru, Nb, Mo, Hf, Ni, Co, Pt, Yb, Tb, Dy, Er, or Pd. For example, the metal silicide layer 172 may include titanium silicide but is not limited thereto.

On the substrate 102, the plurality of source/drain regions 130, a plurality of the metal silicide layer 172, and a plurality of outer insulating spacers 118 may be covered by an insulating liner 142. In embodiments, the insulating liner 142 may be omitted. An inter-gate insulating layer 144 may be on the insulating liner 142. When the insulating liner 142 is omitted, the inter-gate insulating layer 144 may be connected to the plurality of source/drain regions 130.

The insulating liner 142 and the inter-gate insulating layer 144 may be sequentially arranged on the plurality of source/drain regions 130 and the plurality of metal silicide layers 172. The insulating liner 142 and the inter-gate insulating layer 144 may form an insulating structure. In embodiments, the insulating liner 142 may include silicon nitride, SiCN, SiBN, SiON, SiOCN, SiBCN, or a combination thereof but is not limited thereto. The inter-gate insulating layer 144 may include a silicon oxide film but is not limited thereto.

Both side walls of each of the plurality of sub-gate portions 160S included in the plurality of gate lines 160 may be separated from the plurality of source/drain regions 130 with the gate dielectric layer 152 therebetween. The gate dielectric layer 152 may be between the sub-gate portions 160S included in the gate lines 160 and each of the first nanosheet N1, the second nanosheet N2, and the third nanosheet N3, and may be between the sub-gate portions 160S included in the gate lines 160 and the source/drain regions 130.

The plurality of nanosheet stacks NSS may each be on the upper surface FT of each of the plurality of fin-type active regions F1 in areas where the plurality of fin-type active regions F1 intersect the plurality of gate lines 160 and may face the upper surface FT of the fin-type active regions F1 at a position separated from the fin-type active region F1. A plurality of nanosheet transistors may be formed in portions, in which the plurality of fin-type active regions F1 intersect the plurality of gate lines 160, on the substrate 102.

As illustrated in FIGS. 3A and 3B, a plurality of source/drain contacts CA may be respectively arranged on the plurality of source/drain regions 130. The plurality of source/drain contacts CA may each pass through the inter-gate insulating layer 144 and the insulating liner 142 in the vertical direction Z to be connected to the metal silicide layer 172. The plurality of source/drain contacts CA may each be electrically connected to at least one of the source/drain regions 130 through the metal silicide layer 172. The plurality of source/drain contacts CA may each be separated from the main gate portion 160M in the first horizontal direction X with the outer insulating spacer 118 therebetween.

The plurality of source/drain contacts CA may each include a conductive barrier pattern 174 and a contact plug 176 sequentially stacked on one of the source/drain regions 130. The conductive barrier pattern 174 surrounds a bottom surface and a side wall of the contact plug 176 and may be connected to the bottom surface and side wall of the contact plug 176. The plurality of source/drain contacts CA may each be elongated in the vertical direction Z through the inter-gate insulating layer 144 and the insulating liner 142. The conductive barrier pattern 174 may be between the metal silicide layer 172 and the contact plug 176. The conductive barrier pattern 174 may have a surface connected to the metal silicide layer 172 and a surface connected to the contact plug 176. In embodiments, the conductive barrier pattern 174 may include metal or metal nitride. For example, the conductive barrier pattern 174 may include Ti, Ta, W, TiN, TaN, WN, WCN, TiSiN, TaSIN, WSiN, or a combination thereof but is not limited thereto. The contact plug 176 may include molybdenum (Mo), copper (Cu), tungsten (W), cobalt (Co), ruthenium (Ru), manganese (Mn), titanium (Ti), tantalum (Ta), aluminum (Al), a combination thereof, or an alloy thereof but is not limited thereto.

As illustrated in FIG. 3B, at least one of the plurality of source/drain contacts CA that is adjacent to the via power rail VPR may be separated from the via power rail VPR in the second horizontal direction Y.

As illustrated in FIGS. 3A to 3C, upper surfaces of the plurality of source/drain contacts CA, upper surfaces of the plurality of capping insulating patterns 168, and an upper surface of the inter-gate insulating layer 144 may be covered by an upper insulating structure 180. The upper insulating structure 180 may include an etch stop layer 182 and an interlayer insulating layer 184 sequentially stacked on the plurality of source/drain contacts CA, the plurality of capping insulating patterns 168, and the inter-gate insulating layer 144. The etch stop layer 182 may include silicon carbide (SiC), SiN, nitrogen-doped silicon carbide (SiC:N), SiOC, AlN, AlON, AIO, AlOC, or a combination thereof. The interlayer insulating layer 184 may include an oxide film, a nitride film, an ultralow-k (ULK) film having an ultralow dielectric constant K of about 2.2 to about 2.4, or a combination thereof. For example, the interlayer insulating layer 184 may include a tetraethylorthosilicate (TEOS) film, a high density plasma (HDP) oxide film, a boro-phospho-silicate glass (BPSG) film, a flowable chemical vapor deposition (FCVD) oxide film, a SiON film, a SiN film, a SiOC film, SiCOH film, or a combination thereof but is not limited thereto.

As illustrated in FIGS. 3A and 3B, a plurality of source/drain via contacts VA may be respectively arranged on the plurality of source/drain contacts CA. The plurality of source/drain via contacts VA may each pass through the upper insulating structure 180 to be connected to one of the source/drain contacts CA. The plurality of source/drain regions 130 may each be electrically connected to one of the source/drain via contacts VA through the metal silicide layer 172 and one of the source/drain contacts CA. A bottom surface of each of the plurality of source/drain via contacts VA may be connected to an upper surface of one of the source/drain contacts CA. The plurality of source/drain via contacts VA may each include molybdenum (Mo) or tungsten (W) but are not limited thereto.

As illustrated in FIGS. 2 and 3C, a gate contact CB may be on the gate lines 160. The gate contact CB may pass through the upper insulating structure 180 and the capping insulating pattern 168 in the vertical direction Z to be connected to the gate lines 160. A bottom surface of the gate contact CB may be connected to an upper surface of the gate lines 160. The gate contact CB may include molybdenum (Mo), copper (Cu), tungsten (W), cobalt (Co), ruthenium (Ru), manganese (Mn), titanium (Ti), tantalum (Ta), aluminum (Al), a combination thereof, or an alloy thereof, but a constituent material of the contact plug CB is not limited thereto. In embodiments, the gate contact CB may further include a conductive barrier pattern surrounding part of a contact plug. The conductive barrier pattern included in the gate contact CB may include metal or metal nitride. For example, the conductive barrier pattern may include Ti, Ta, W, TiN, TaN, WN, WCN, TiSiN, TaSiN, WSiN, or a combination thereof but is not limited thereto.

The via power rail VPR may pass through the upper insulating structure 180, the capping insulating pattern 168, the gate lines 160, the inter-gate insulating layer 144, the insulating liner 142, and the device isolation layer 112 in the vertical direction Z. The insulating spacer 189 may surround a side wall of the via power rail VPR and pass through the upper insulating structure 180, the capping insulating pattern 168, the gate line 160, the inter-gate insulating layer 144, and the insulating liner 142 in the vertical direction Z and pass through part of the device isolation layer 112 in the vertical direction Z. A portion of the gate lines 160 through which the via power rail VPR and the insulating spacer 189 pass may be a region between the plurality of nanosheet stacks NSS. The via power rail VPR may be separated from the gate lines 160 in a horizontal direction, for example, the second horizontal direction Y, with the insulating spacer 189 therebetween. The via power rail VPR and the insulating spacer 189 may be separated from a pair of source/drain regions 130 and a pair of fin-type active regions F1 in a horizontal direction, for example, the second horizontal direction.

In embodiments, both side walls LS1 of the first portion LVR1 of the via power rail VPR may respectively face the pair of fin-type active regions F1, and both side walls US1 of the second portion UVR1 may respectively face the pair of fin-type active regions F1. Both side walls LS1 of the first portion LVR1 may be inclined to be closer to the pair of fin-type active regions F1 as both side walls LS1 come closer to the backside power rail BPW. Also, both side walls US1 of the second portion UVR1 may be inclined to be farther away from the pair of fin-type active regions F1 as both side walls US1 come closer to the first portion LVR1.

In embodiments, an upper surface of the via power rail VPR, an upper surface of the upper insulating structure 180, an upper surface of each of the plurality of source/drain via contacts VA, and an upper surface of the gate contact CB may be coplanar with each other.

The upper surface of each of the upper insulating structure 180, an upper surface of the backside power rail BPW, the upper surface of each of the plurality of source/drain via contacts VA, and the upper surface of the gate contact CB may be covered by the upper insulating layer 192. A constituent material of the upper insulating layer 192 is substantially the same as the constituent material of the interlayer insulating layer 184 described above.

A plurality of upper wiring layers M1 may pass through the upper insulating layer 192. The plurality of upper wiring layers M1 may each be connected to one from among the plurality of source/drain via contacts VA located below, or one from among the plurality of gate contacts CB (see FIG. 2). The plurality of upper wiring layers M1 may each include molybdenum (Mo), copper (Cu), tungsten (W), cobalt (Co), ruthenium (Ru), manganese (Mn), titanium (Ti), tantalum (Ta), aluminum (Al), a combination thereof, or an alloy thereof but is not limited thereto.

The plurality of upper wiring layers M1 may each include a power connection conductive layer PCL connected to the via power rail VPR on the via power rail VPR. One from among the plurality of source/drain via contacts VA may connect the source/drain contact CA to the power connection conductive layer PCL at a position separated from the via power rail VPR in the second horizontal direction Y. One of the source/drain regions 130 that is connected to the via power rail VPR among the plurality of source/drain regions 130 may be electrically connected to the via power rail VPR through one of the source/drain contacts CA, one of the source/drain via contacts VA, and the power connection conductive layer PCL.

As described with reference to FIGS. 2, 3A, 3B, 3C, and 3D, the via power rail VPR of the integrated circuit device 100 may have the first portion LVR1 of which a cross-sectional area increases from an upper part toward a lower part, and the second portion UVR1 of which a cross-sectional area decreases from an upper part toward a lower part. As the via power rail VPR has the first portion LVR1 of which the cross-sectional area increases from the upper part toward the lower part, a contact area between the via power rail VPR and backside power rail BPW may be increased, electrical resistance may be reduced, and thus, an integrated circuit device 100 with improved electrical characteristics and reliability may be provided.

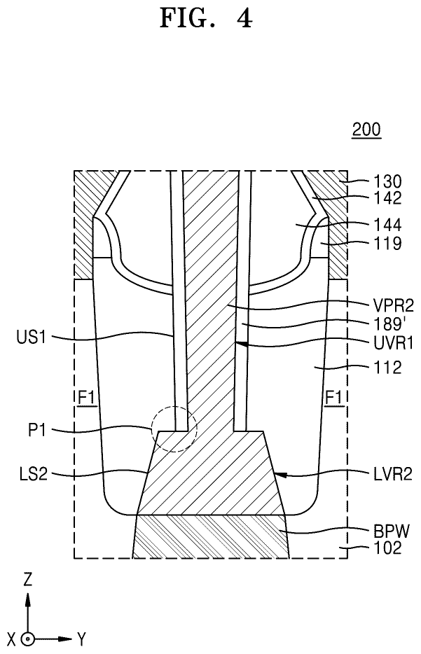

FIG. 4 is a view illustrating an integrated circuit device 200 according to another embodiment. FIG. 4 illustrates a portion corresponding to a region “EX2” of FIG. 3B. The integrated circuit device 200 may form part of the plurality of logic cells LC illustrated in FIG. 1. In FIG. 4, the same reference numerals as in FIGS. 2, 3A, 3B, 3C, and 3D indicate the same members, and redundant descriptions thereof may be omitted below.

Referring to FIG. 4, the integrated circuit device 200 has substantially the same configuration as the integrated circuit device 100 described with reference to FIGS. 2, 3A, 3B, 3C, and 3D. However, the integrated circuit device 200 may include a via power rail VPR2 including a first portion LVR2 instead of the via power rail VPR including the first portion LVR1 of the integrated circuit device 100 described with reference to FIGS. 2, 3A, 3B, 3C, and 3D, and may include an insulating spacer 189′ instead of the insulating spacer 189.

As illustrated in FIG. 4, the first portion LVR2 may have a shape of which a width in the second horizontal direction Y uniformly increases from the top toward the bottom, while the second portion UVR1 may have a shape of which a width in the second horizontal direction Y uniformly decreases from the top toward the bottom. For example, the first portion LVR2 may have a shape of which a width in the second horizontal direction Y uniformly increases toward the backside surface 102B of the substrate 102, while the second portion UVR1 may have a shape of which a width in the second horizontal direction Y uniformly decreases toward the backside surface 102B of the substrate 102. A cross-sectional area of the first portion LVR2 may increase from the top toward the bottom, and a cross-sectional area of the second portion UVR1 may decrease from the top toward the bottom. Likewise, a cross-sectional area of the first portion LVR2 may increase toward the backside surface 102B, and a cross-sectional area of the second portion UVR1 may decrease toward the backside surface 102B.

Because a pair of fin-type active regions F1 are separated from the first portion LVR2, the greatest width of the first portion LVR2 may be less than a separation distance between the pair of fin-type active regions F1. The smallest width of the first portion LVR2 may be greater than the smallest width of the second portion UVR1.

In embodiments, when the via power rail VPR is cut in the second horizontal direction Y, the first portion LVR2 may have a trapezoidal cross-section, and the second portion UVR1 may have an inverse trapezoidal cross-section. For example, the first portion LVR2 may include two side walls LS2 that are inclined surfaces, and the second portion UVR1 may include two side walls US1, which are inclined surfaces, in a direction different from another direction in which both side walls LS2 of the first portion LVR2 are inclined. Both side walls LS2 of the first portion LVR2 may be side walls of a hexahedron having a trapezoidal cross-section, and both side walls US1 of the second portion UVR1 may be side walls of a hexahedron having an inverse trapezoidal cross-section.

In embodiments, the side walls of the via power rail VPR2 facing the pair of fin-type active regions F1 may each have a step structure P1. For example, both side walls of the first portion LVR2 may be separated from both side walls of the second portion UVR1 in a horizontal direction, for example, the horizontal direction Y at a position where the first portion LVR2 meets the second portion UVR1, and an upper surface of the first portion LVR2 may be between both side walls LS2 of the first portion LVR2 and both side walls US1 of the second portion UVR1.

A part of a side wall of the via power rail VPR may be covered by the insulating spacer 189′. For example, the insulating spacer 189′ may not cover the side walls LS2 of the first portion LVR2 of the via power rail VPR but may entirely cover the side wall US1 of the second portion UVR1. The insulating spacer 189′ may conformally extend along the side wall US1 of the second portion UVR1 to be connected to an upper surface of the first portion LVR2. In embodiments, the insulating spacer 189′ may include a silicon oxide film, a silicon oxynitride film, or a combination thereof.

The side walls LS2 of the first portion LVR2 of the via power rail VPR may not be covered by the insulating spacer 189′, but the side walls US1 of the second portion UVR1 may be covered by the insulating spacer 189′. For example, the first portion LVR2 may be connected to a device isolation layer 112, but the second portion UVR1 may be separated from the device isolation layer 112 with the insulating spacer 189′ therebetween.

In embodiments, both side walls LS2 of the first portion LVR2 of the via power rail VPR may respectively face a pair of fin-type active regions F1, and both side walls US1 of the second portion UVR1 may respectively face the pair of fin-type active regions F1. Both side walls LS2 of the first portion LVR2 may be inclined to come closer to the pair of fin-type active regions F1 as both side wall LS2 approach the backside power rail BPW. Also, both side walls US1 of the second portion UVR1 may be inclined to be farther away from the pair of fin-type active regions F1 as both side walls US1 apparoach the first portion LVR2.

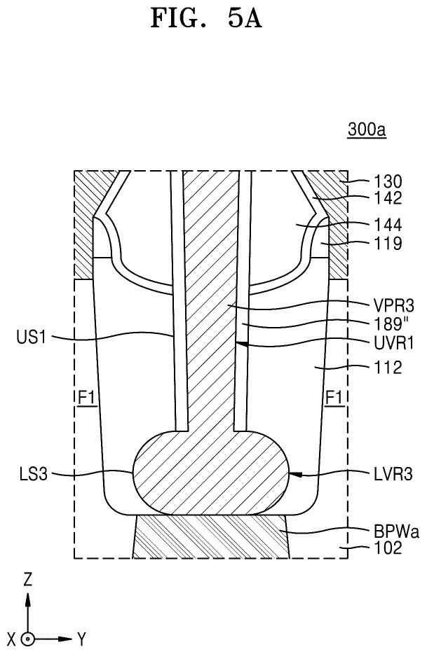

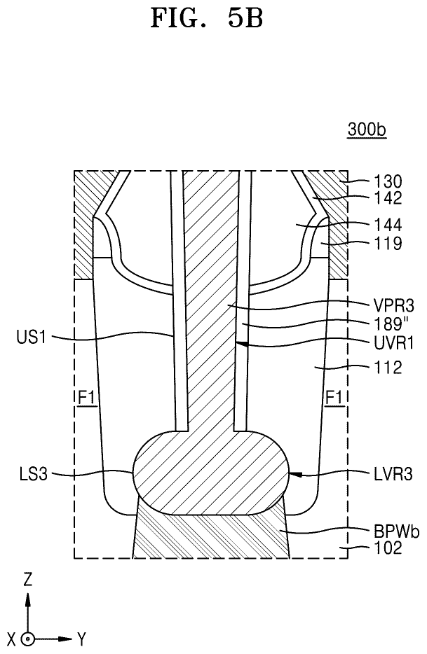

FIG. 5A is a view illustrating an integrated circuit device according to another embodiment. FIG. 5A illustrates a portion corresponding to a region “EX2” of FIG. 3B. An integrated circuit device 300a may form part of the plurality of logic cells LC illustrated in FIG. 1. In FIG. 5A, the same reference numerals as in FIGS. 2, 3A, 3B, 3C, and 3D indicate the same members, and redundant descriptions thereof may be omitted below.

Referring to FIG. 5A, the integrated circuit device 300a may have substantially the same configuration as the integrated circuit device 100 described with reference to FIGS. 2, 3A, 3B, 3C, and 3D. However, the integrated circuit device 300a may include a via power rail VPR3 including a first portion LVR3 instead of the via power rail VPR including the first portion LVR1 of the integrated circuit device 100 described with reference to FIGS. 2, 3A, 3B, 3C, and 3D, and may include an insulating spacer 189″ instead of the insulating spacer 189.

As illustrated in FIG. 5A, the first portion LVR3 may have a shape of which a width in the second horizontal direction Y increases and then decreases from the top toward the bottom, while a second portion UVR1 may have a shape of which a width in the second horizontal direction Y decreases from the top toward the bottom. For example, the first portion LVR3 may have a shape of which a width in the second horizontal direction Y increases and then decreases toward the backside surface 102B of the substrate 102, while the second portion UVR1 may have a shape of which a width in the second horizontal direction Y uniformly decreases toward the backside surface 102B of the substrate 102. For example, the width of the first portion LVR3 in the second horizontal direction Y in the middle portion may be relatively great compared to a width of the first portion LVR3 in the second horizontal direction Y at upper and lower portions of the first portion LVR3. A cross-sectional area of the first portion LVR3 may increase and then decrease from the top toward the bottom, and a cross-sectional area of the second portion UVR1 may decrease from the top toward the bottom. Likewise, the first portion LVR3 may have a shape of which a cross-sectional area increases and then decreases toward the backside surface 102B of the substrate 102, while the second portion UVR1 may have a shape of which a cross-sectional area uniformly decreases toward the backside surface 102B of the substrate 102.

Because the pair of fin-type active regions F1 are separated from the first portion LVR3, the greatest width of the first portion LVR3 may be less than a separation distance between the pair of fin-type active regions F1. The smallest width of the first portion LVR3 may be the same as the smallest width of the second portion UVR1.

In embodiments, when the via power rail VPR is cut in the second horizontal direction Y, the first portion LVR3 may have a cross-section including part of a circle or part of an ellipse, and the portion UVR1 may have a trapezoidal cross-section having an upper part wider than a lower part of the trapezoidal cross-section. For example, the first portion LVR3 may include two curved side walls LS3, and the second portion UVR1 may include two side walls US1 that are inclined surfaces of the first portion LVR3. In embodiments, both side walls LS3 of the first portion LVR3 may be connected to ends of both side walls US1 of the second portion UVR1.

A part of a side wall of the via power rail VPR may be covered by an insulating spacer 189″. For example, the insulating spacer 189″ may not cover both side walls LS3 of the first portion LVR3 of the via power rail VPR but may entirely cover both side walls US1 of the second portion UVR1. The insulating spacer 189″ may conformally extend along the side walls US1 of the second portion UVR1 to be connected to the side walls LS3 of the first portion LVR3. In embodiments, the insulating spacer 189″ may include a silicon oxide film, a silicon oxynitride film, or a combination thereof.

The side walls LS3 of the first portion LVR3 of the via power rail VPR may not be covered by the insulating spacer 189″, but the side walls US1 of the second portion UVR1 may be covered by the insulating spacer 189″. For example, the first portion LVR3 may be connected to a device isolation layer 112, but the second portion UVR1 may be separated from the device isolation layer 112 with an insulating spacer 189″ therebetween.

In embodiments, both side walls LS3 of the first portion LVR3 of the via power rail VPR may respectively face the pair of fin-type active regions F1, and both side walls US1 of the second portion UVR1 may respectively face the pair of fin-type active regions F1. Both side walls LS3 of the first portion LVR3 may have a convex shape toward the pair of fin-type active regions F1. For example, both side walls LS3 of the first portion LVR3 may be closest to the pair of fin-type active regions F1 at a middle portion of the first portion LVR3 rather than at upper and lower portions of the first portion LVR3. Also, both side walls US1 of the second portion UVR1 may be inclined to be farther away from the pair of fin-type active regions F1 as both side walls US1 approach the first part LVR3.

The via power rail VPR may be connected to the center region of the backside power rail BPWa but may be separated from an edge region of the backside power rail BPWa. A part of the device isolation layer 112 may be between the via power rail VPR and the edge area of the backside power rail BPWa. A separation distance in the vertical direction Z between the via power rail VPR and the backside power rail BPWa may increase toward the edge of the backside power rail BPWa.

FIG. 5B is a view illustrating an integrated circuit device 300b according to another embodiment. FIG. 5B illustrates a portion corresponding to a region “EX2” of FIG. 3B. The integrated circuit device 300b may form part of a plurality of logic cells LC illustrated in FIG. 1. In FIG. 5B, the same reference numerals as in FIGS. 2, 3A, 3B, 3C, and 3D indicate the same members, and redundant descriptions thereof may be omitted below.

Referring to FIG. 5B, the integrated circuit device 300b may have substantially the same configuration as the integrated circuit device 100 described with reference to FIGS. 2, 3A, 3B, 3C, and 3D. However, the integrated circuit device 300b may include a via power rail VPR3 including a first portion LVR3 instead of the via power rail VPR including the first portion LVR1 of the integrated circuit device 100 described with reference to FIGS. 2, 3A, 3B, 3C, and 3D, and may include an insulating spacer 189″ instead of the insulating spacer 189.

As illustrated in FIG. 5B, the first portion LVR3 may have a shape of which a width in the second horizontal direction Y increases and then decreases from the top toward the bottom, while the second portion UVR1 may have a shape of which a width in the second horizontal direction Y decreases from the top to the bottom. Specific shapes of the first portion LVR3 and the second portion UVR1 are similar to the shapes described with reference to FIG. 5A.

A part of a side wall of the via power rail VPR may be covered by the insulating spacer 189″. For example, the insulating spacer 189″ may not cover side walls LS3 of the first part LVR3 of the via power rail VPR but may entirely cover side walls US1 of the second portion UVR1. The insulating spacer 189″ may conformally extend along the side walls US1 of the second portion UVR1 to be connected to the side walls LS3 of the first portion LVR3. In embodiments, the insulating spacer 189″ may include a silicon oxide film, a silicon oxynitride film, or a combination thereof.

The side walls LS3 of the first portion LVR3 of the via power rail VPR may not be covered by the insulating spacer 189″, but the side walls US1 of the second portion UVR1 may be covered by the insulating spacer 189″. For example, the first portion LVR3 may be connected to the device isolation layer 112, but the second portion UVR1 may be separated from the device isolation layer 112 with the insulating spacer 189″ therebetween.

In embodiments, both side walls LS3 of the first portion LVR3 of the via power rail VPR may respectively face a pair of fin-type active regions F1, and both side walls US1 of the second portion UVR1 may respectively face a pair of fin-type active regions F1. Shapes of both side walls LS3 of the first part LVR3 and both side walls US1 of the second portion UVR1 are similar to the shapes described with reference to FIG. 5A.

The via power rail VPR may be connected to a central region of the backside power rail BPWb and an edge region of the backside power rail BPWb. The edge region of the backside power rail BPWb may extend through the device isolation layer 112 to be connected to one end of the via power rail VPR. The backside power rail BPWb may have a greater height in the edge region in the vertical direction Z than a height in the central region in the vertical direction Z. For example, the backside power rail BPWb may have a concave shape in the center.

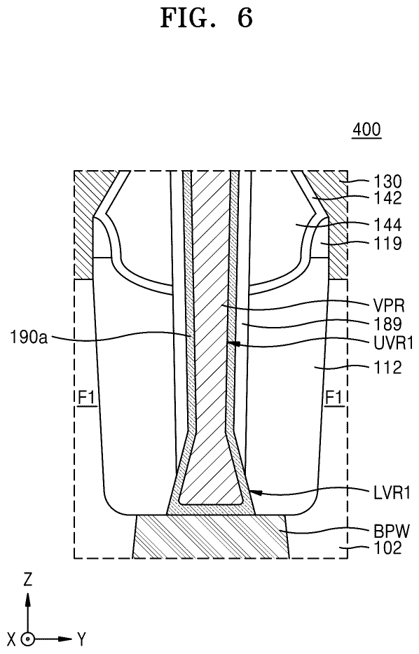

FIG. 6 is a view illustrating an integrated circuit device 400 according to another embodiment. FIG. 6 illustrates a portion corresponding to a region “EX2” of FIG. 3B. The integrated circuit device 400 may form part of the plurality of logic cells LC illustrated in FIG. 1. In FIG. 6, the same reference numerals as in FIGS. 2, 3A, 3B, 3C, and 3D indicate the same members, and redundant descriptions thereof may be omitted below.

Referring to FIG. 6, the integrated circuit device 400 may have substantially the same configuration as the integrated circuit device 100 described with reference to FIGS. 2, 3A, 3B, 3C, and 3D. However, unlike the configurations described with reference to FIGS. 2, 3A, 3B, 3C, and 3D, the integrated circuit device 400 may further include a conductive barrier layer 190a between a via power rail VPR and an insulating spacer 189, and between the via power rail VPR and a backside power rail BPW.

In embodiments, the via power rail VPR may include a first metal wiring layer. The first metal wiring layer may include a low-resistance metal, for example, Ru, Co, W, Mo, Cu, Rh, Ir, Ti, or a combination thereof.

The conductive barrier layer 190a may cover a lower surface and both side walls of the via power rail VPR. The conductive barrier layer 190a may include Ti, TiN, TaN, WN, WCN, TiSiN, TaSiN, WSiN, or a combination thereof but is not limited thereto.

The conductive barrier layer 190a may include a portion between the via power rail VPR and the backside power rail BPW and may include a portion between the via power rail VPR and the insulating spacer 189. The via power rail VPR may be separated from the backside power rail BPW in the vertical direction Z with the conductive barrier layer 190a therebetween and may be separated from the insulating spacer 189 in a horizontal direction, for example, the second horizontal direction Y, with the conductive barrier layer 190a therebetween.

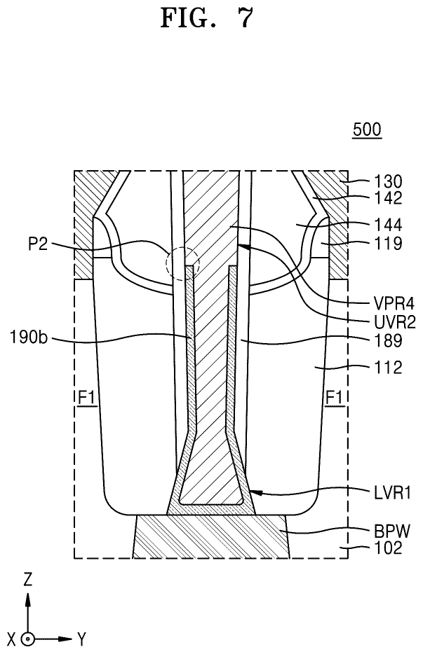

FIG. 7 is a view illustrating an integrated circuit device 500 according to another embodiment. FIG. 7 illustrates a portion corresponding to a region “EX2” of FIG. 3B. The integrated circuit device 500 may form part of the plurality of logic cells LC illustrated in FIG. 1. In FIG. 7, the same reference numerals as in FIGS. 2, 3A, 3B, 3C, and 3D indicate the same members, and redundant descriptions thereof may be omitted below.

Referring to FIG. 7, the integrated circuit device 500 may have substantially the same configuration as the integrated circuit device 100 described with reference to FIGS. 2, 3A, 3B, 3C, and 3D. However, the integrated circuit device 500 may include a via power rail VPR4 including a second portion UVR2 instead of the via power rail VPR including the second portion UVR1 described with reference to FIGS. 2, 3A, 3B, 3C, and 3D, and may further include a conductive barrier layer 190b between the via power rail VPR4 and the insulating spacer 189.

In embodiments, the via power rail VPR4 may include a first metal wiring layer. The first metal wiring layer may include a low-resistance metal, for example, Ru, Co, W, Mo, Cu, Rh, Ir, Ti, or a combination thereof.

The conductive barrier layer 190b may cover a lower surface of the via power rail VPR4 and a part of both side walls of the via power rail VPR4. For example, the conductive barrier layer 190b may entirely cover the lower surface and both side walls of the first portion LVR1 of the via power rail VPR4 and cover only a part of both side walls of the second portion UVR2. An upper surface of the conductive barrier layer 190b may be at various vertical levels but is not limited to what is illustrated. The conductive barrier layer 190b may include Ti, TiN, TaN, WN, WCN, TiSiN, TaSIN, WSiN, or a combination thereof but is not limited thereto.

The conductive barrier layer 190b may include a portion between the via power rail VPR4 and the backside power rail BPW and may include a portion between the via power rail VPR4 and the insulating spacer 189. The via power rail VPR4 may be separated from the backside power rail BPW in the vertical direction Z with the conductive barrier layer 190b therebetween. An upper portion of the via power rail VPR4 may be separated from an inter-gate insulating layer 144 in a horizontal direction, for example, the second horizontal direction Y, with the insulating spacer 189 therebetween. A middle portion of the via power rail VPR4 may be separated from a device isolation layer 112 in a horizontal direction, for example, the second horizontal direction Y, with the insulating spacer 189 and the conductive barrier layer 190b therebetween. A lower portion of the via power rail VPR4 may be separated from the device isolation layer 112 in a horizontal direction, for example, the second horizontal direction Y, with the conductive barrier layer 190b therebetween.

The via power rail VPR4 may include a first portion LVR1 connected to the backside power rail BPW and a second portion UVR2 on the first portion LVR1. In embodiments, the second portion UVR2 may have a shape of which a width in the second horizontal direction Y uniformly decreases from the top toward the bottom and may include a step structure P2. For example, an upper surface of the conductive barrier layer 190b may be between a portion of a side wall of the second portion UVR2, which is covered by the conductive barrier layer 190b, and a portion of a side wall of the second portion UVR2, which is not covered and is exposed by the conductive barrier layer 190b.

In embodiments, the first portion LVR1 may also include a step structure P2, and, in this case, the upper surface of the conductive barrier layer 190b may be between a portion of a sidewall of the first portion LVR1 which is covered by the conductive barrier layer 190b and a portion of a sidewall of the first portion LVR1 which is not covered and is exposed by the conductive barrier layer 190b.

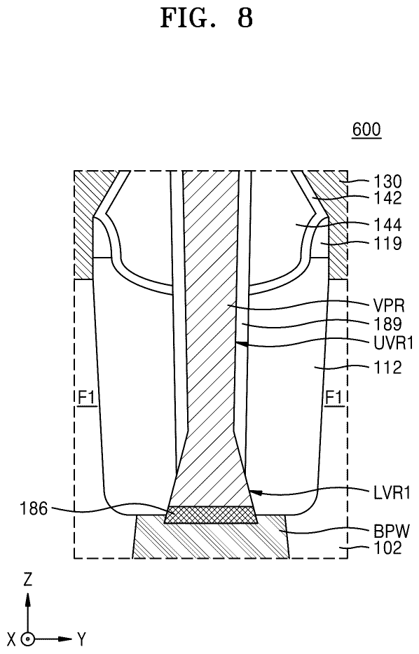

FIG. 8 is a view illustrating an integrated circuit device 600 according to another embodiment. FIG. 8 illustrates a portion corresponding to a region “EX2” of FIG. 3B. The integrated circuit device 600 may form part of a plurality of logic cells LC illustrated in FIG. 1. In FIG. 8, the same reference numerals as in FIGS. 2, 3A, 3B, 3C, and 3D indicate the same members, and redundant descriptions thereof may be omitted below.

Referring to FIG. 8, the integrated circuit device 600 may have substantially the same configuration as the integrated circuit device 100 described with reference to FIGS. 2, 3A, 3B, 3C, and 3D. However, unlike the configuration described with reference to FIGS. 2, 3A, 3B, 3C, and 3D, the integrated circuit device 600 may further include a metal wiring silicide layer 186 covering a lower surface of a via power rail VPR.

In embodiments, the via power rail VPR may include a first metal wiring layer. The first metal wiring layer may include a first metal, and the first metal may include, for example, Ru, Co, W, Mo, Cu, Rh, Ir, Ti, or a combination thereof.

The metal wiring silicide layer 186 may include the first metal and may include a combination of the first metal and silicon. For example, when the first metal wiring layer forming the via power rail VPR includes Mo, the metal wiring silicide layer 186 may include a combination of Mo and Si.

The metal wiring silicide layer 186 may be between the via power rail VPR and a backside power rail BPW. The metal wiring silicide layer 186 may include a portion that overlaps the backside power rail BPW in the second horizontal direction Y. For example, a vertical level of a lower surface of the metal wiring silicide layer 186 may be between a vertical level of an upper surface of the backside power rail BPW and a vertical level of a lower surface of the backside power rail BPW. The via power rail VPR may be separated from the backside power rail BPW with the metal wiring silicide layer 186 therebetween.

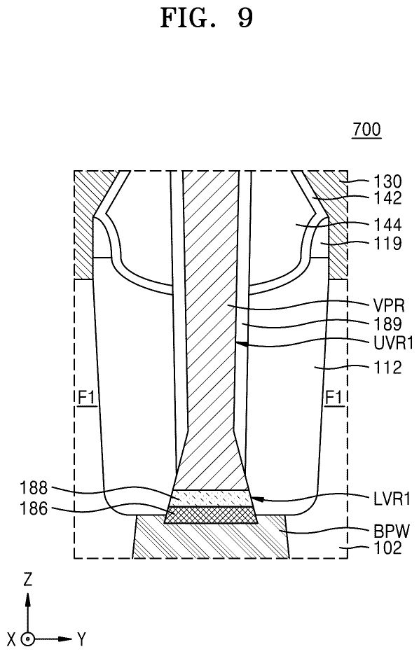

FIG. 9 is a view illustrating an integrated circuit device 700 according to another embodiment. FIG. 9 illustrates a portion corresponding to a region “EX2” of FIG. 3B. The integrated circuit device 700 may form part of a plurality of logic cells LC illustrated in FIG. 1. In FIG. 9, the same reference numerals as in FIGS. 2, 3A, 3B, 3C, and 3D indicate the same members, and redundant descriptions thereof may be omitted below.

Referring to FIG. 9, the integrated circuit device 700 may have substantially the same configuration as the integrated circuit device 100 described with reference to FIGS. 2, 3A, 3B, 3C, and 3D. However, unlike the configuration described with reference to FIGS. 2, 3A, 3B, 3C, and 3D, the integrated circuit device 700 may further include a metal wiring silicide layer 186 and a connection metal layer 188 between a via power rail VPR and a backside power rail BPW.

In embodiments, the via power rail VPR may include a first metal wiring layer. The first metal wiring layer may include a first metal, and the first metal may include, or example, Ru, Co, W, Mo, Cu, Rh, Ir, Ti, or a combination thereof.

The metal wiring silicide layer 186 may include the first metal and may include a combination of the first metal and silicon. For example, when the first metal wiring layer forming the via power rail VPR may include Mo, the metal wiring silicide layer 186 may include a combination of Mo and Si.

The metal wiring silicide layer 186 may be between the via power rail VPR and the backside power rail BPW. The metal wiring silicide layer 186 may include a portion that overlaps the backside power rail BPW in the second horizontal direction Y. For example, a vertical level of a lower surface of the metal wiring silicide layer 186 may be between a vertical level of an upper surface of the backside power rail BPW and a vertical level of a lower surface of the backside power rail BPW.

The connection metal layer 188 may be between the metal wiring silicide layer 186 and the via power rail VPR. The connection metal layer 188 may cover a lower surface of the via power rail VPR and an upper surface of the metal wiring silicide layer 186. The connection metal layer 188 may include a second metal, and the second metal may include, for example, Ru, Co, W, Mo, Cu, Rh, Ir, Ti, or a combination thereof. The second metal forming the connection metal layer 188 may be different from the first metal. For example, when the first metal wiring layer forming the via power rail VPR includes Mo, the connection metal layer 188 may include W, Ru, Co, Cu, Rh, Ir, Ti, or a combination thereof. The via power rail VPR may be separated from the backside power rail BPW with the metal wiring silicide layer 186 and the connection metal layer 188 therebetween.

Like the integrated circuit device 100 described with reference to FIGS. 2, 3A, 3B, 3C, and 3D, the via power rails VPR, VPR2, VPR3, and VPR4 of the integrated circuit devices 200, 300, 400, 500, 600, and 700 described with reference to FIGS. 4 to 9 include the first portions LVR1, LVR2, and LVR3, and accordingly, the via power rails VPR, VPR2, VPR3, and VPR4 may have relatively great areas connected to the backside power rail BPW, the metal wiring silicide layer 186, or the connection metal layer 188. As a result, an integrated circuit device with low electrical resistance and increased reliability and electrical characteristics may be provided.

Next, methods of manufacturing integrated circuit devices according to embodiments are described.

FIGS. 10, 11, 12A, 12B, 12C, 13, 14A, 14B, 14C, 15, 16, 17, 18A, 18B, 18C, 19A, 19B, 19C, 20A, 20B, 21A, 21B, 22A, 22B, 23A, 23B, 23C, 24A, 24B, 25A, 25B, 26A, 26B and 26C are views illustrating in process sequence a method of manufacturing an integrated circuit device, according to an embodiment.

For example, FIGS. 10, 11, 12B, 13, 14B, 18B, 19B, 20A, 21A, 22A, 23A, 24A, 25A, and 26B are cross-sectional views illustrating cross-sectional structures according to a process sequence of a portion corresponding to a cross-section taken along line Y1-Y1′ of FIG. 2, and FIGS. 12A, 14A, 15, 16, 17, 18A, 19A, and 26A are cross-sectional views illustrating cross-sectional structures according to a process sequence of a portion corresponding to a cross-section taken along line X1-X1′ of FIG. 2, and FIGS. 12C, 14C, 18C, 19C, 20B, 21B, 22B, 23B, 24B, 25B, and 26C are cross-sectional views illustrating cross-sectional structures according to a process sequence of a portion corresponding to a cross-section taken along line Y2-Y2′ of FIG. 2.

In FIGS. 10, 11, 12A, 12B, 12C, 13, 14A, 14B, 14C, 15, 16, 17, 18A, 18B, 18C, 19A, 19B, 19C, 20A, 20B, 21A, 21B, 22A, 22B, 23A, 23B, 23C, 24A, 24B, 25A, 25B, 26A, 26B, and 26C, the same reference numerals as in FIGS. 2, 3A, 3B, 3C, and 3D indicate the same members, and detailed descriptions thereof may be omitted below.

Referring to FIG. 10, a plurality of sacrificial semiconductor layers 103 and a plurality of nanosheet semiconductor layers NS may be alternately stacked on the substrate 102.

The plurality of sacrificial semiconductor layers 103 and the plurality of nanosheet semiconductor layers NS may include semiconductor materials with different etch selection ratios. In embodiments, the plurality of nanosheet semiconductor layers NS may each include a Si layer, and the plurality of sacrificial semiconductor layers 103 may each include a SiGe layer. In embodiments, Ge content of each of the plurality of sacrificial semiconductor layers 103 may be constant. The SiGe layer constituting each of the plurality of sacrificial semiconductor layers 103 may have constant Ge content selected in a range of about 5 atomic % to about 60 atomic %, for example, about 10 atomic % to about 40 atomic %. The Ge content of the SiGe layer constituting each of the plurality of sacrificial semiconductor layers 103 may be selected in various ways as needed.

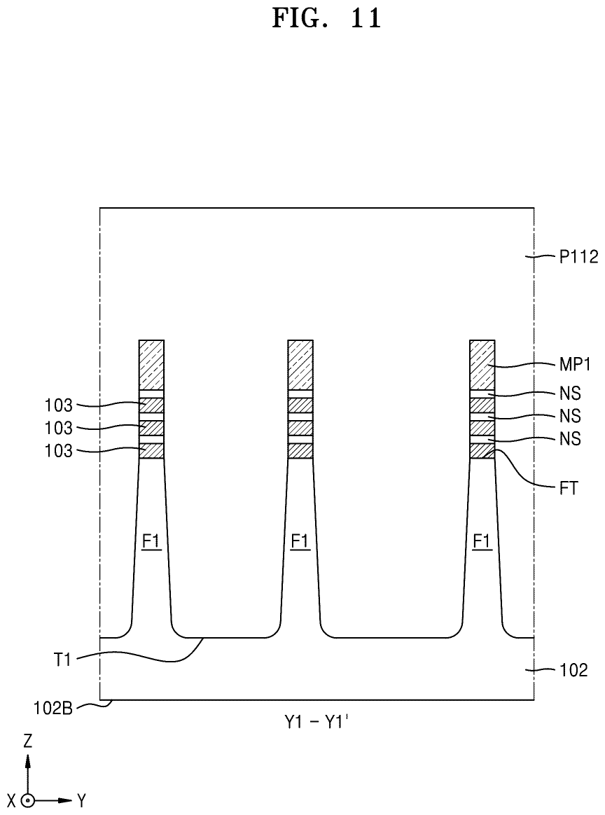

Referring to FIG. 11, after mask patterns MP1 are formed on a resulting construct of FIG. 10, the plurality of sacrificial semiconductor layers 103, the plurality of nanosheet semiconductor layers NS, and part of the substrate 102 may be etched by using the mask pattern MP1 as an etch mask to form a plurality of fin-type active regions F1 on the substrate 102. A plurality of trench regions T1 may be defined on the substrate 102 by the plurality of fin-type active regions F1. In embodiments, mask patterns MP1 may each have a stacked structure of an oxide film pattern and a silicon nitride film pattern. The mask patterns MP1 may extend parallel to each other in the first horizontal direction X on the substrate 102. A stacked structure of the plurality of sacrificial semiconductor layers 103 and the plurality of nanosheet semiconductor layers NS may be on an upper surface FT of each of the plurality of fin-type active regions F1.

Thereafter, a device isolation insulating layer P112 may be formed on the obtained resulting structure. The device isolation insulating layer P112 may be formed to have a thickness sufficient to fill the remaining spaces of the plurality of trench regions T1 on the substrate 102. The device isolation insulating layer P112 may include a silicon oxide film.

In order to form the device isolation insulating layer P112, plasma enhanced chemical vapor deposition (PECVD), high density plasma (HDP) CVD, inductively coupled plasma (ICP) CVD, capacitor coupled plasma (CCP) CVD, flowable chemical vapor deposition (FCVD), a spin coating processes, and so on may be used.

Referring to FIGS. 12A, 12B, and 12C, after the resulting structure of FIG. 11 is planarized to expose an upper surface of the mask patterns MP1, the mask patterns MP1, that are exposed, may be removed, and a recess process for removing part of the device isolation insulating layer P112 may be performed to the isolation insulating layer P112. As a result, the plurality of sacrificial semiconductor layers 103 and the plurality of nanosheet semiconductor layers NS (see FIG. 11) may protrude onto an upper surface of the device isolation layer 112.

In order to perform the recess process of the device isolation insulating layer P112, a dry etching process, a wet etching process, or a combination of the dry and wet etching processes may be used. In this case, a wet etching process using NH4OH, tetramethyl ammonium hydroxide (TMAH), potassium hydroxide (KOH), and so on as an etchant, or a dry etching process using inductively coupled plasma (ICP), transformer coupled plasma (TCP), electron cyclotron resonance (ECR), reactive ion etch (RIE), and so on may be used. When a recess process for the device isolation insulating layer P112 is perform by using the dry etching process, a fluorine-containing gas, such as CF4, a chlorine-containing gas, such as C12, HBr, and so on may be used as etching gas.

Thereafter, a plurality of dummy gate structures DGS may be formed on the stacked structure of the plurality of sacrificial semiconductor layers 103 and the plurality of nanosheet semiconductor layers NS. The plurality of dummy gate structures DGS may be elongated in the second horizontal direction Y. The plurality of dummy gate structures DGS may each have a structure in which an oxide film D122, a dummy gate layer D124, and a capping layer D126 are sequentially stacked. In embodiments, the oxide film D122 may be a film obtained by oxidizing surfaces of the plurality of sacrificial semiconductor layers 103 and surfaces of the plurality of nanosheet semiconductor layers NS (see FIG. 12). The dummy gate layer D124 may include polysilicon, and the capping layer D126 may include a silicon nitride film.

After a plurality of outer insulating spacers 118 are provided to cover both side walls of each of the plurality of dummy gate structures DGS, the plurality of sacrificial semiconductor layers 103, the plurality of nanosheet semiconductor layers NS, and the fin-type active region F1 may be partially etched by using the plurality of dummy gate structures DGS and the plurality of outer insulating spacers 118 as etch masks to divide the plurality of nanosheet semiconductor layers NS into a plurality of nanosheet stacks NSS each including a first nanosheet N1, a second nanosheet N2, and a third nanosheet N3. As a result, a plurality of active region recesses R1 may be formed on the fin-type active regions F1. In order to form the plurality of active region recesses R1, etching may be performed by using dry etching, wet etching, or a combination thereof. After the plurality of active region recesses R1 are formed, a plurality of recess side insulating spacers 119 arranged adjacent to the plurality of active region recesses R1 may be formed on the device isolation layer 112 on both sides of the fin-type active regions F1.

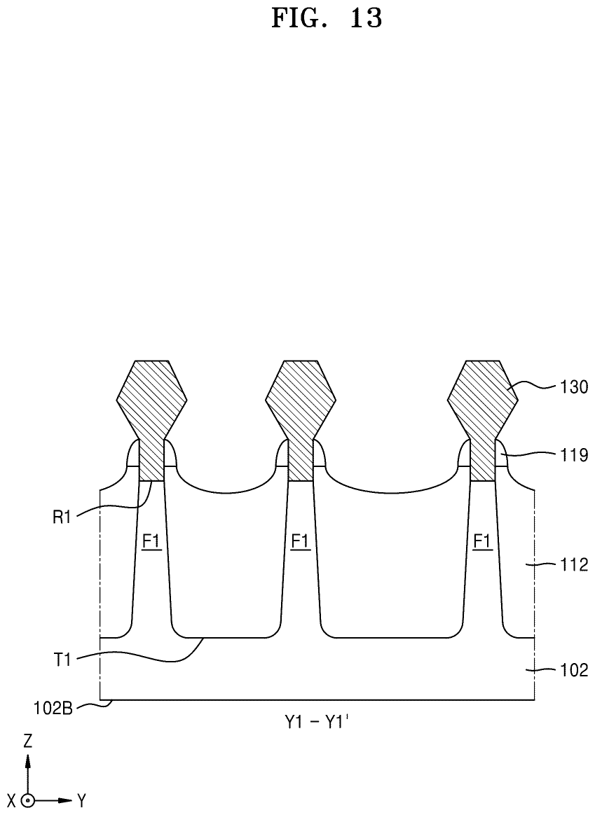

Referring to FIG. 13, a plurality of source/drain regions 130 filling the plurality of active region recesses R1 may be formed in a resulting structure of FIGS. 12A, 12B, and 12C.

In order to form the plurality of source/drain regions 130, a semiconductor material may be epitaxially grown from a surface of the fin-type active regions F1 exposed at a bottom surface of the plurality of active region recesses R1 and side walls of each of the first nanosheet N1, the second nanosheet N2, and the third nanosheet N3 included in the nanosheet stack NSS.

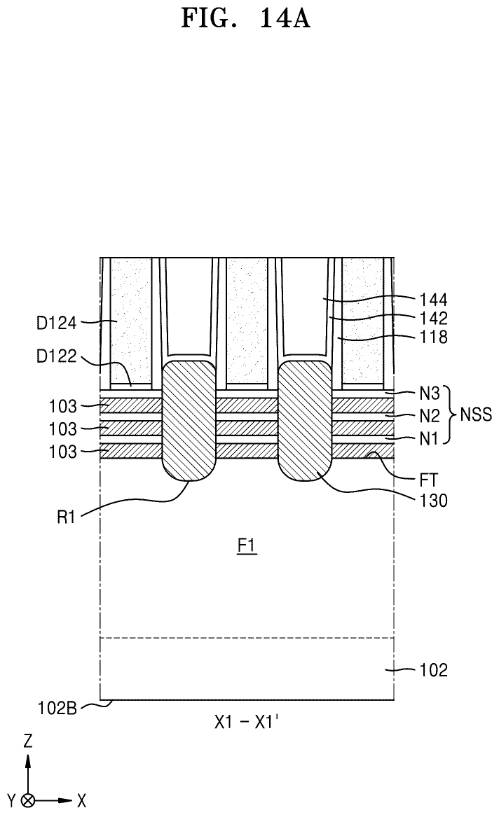

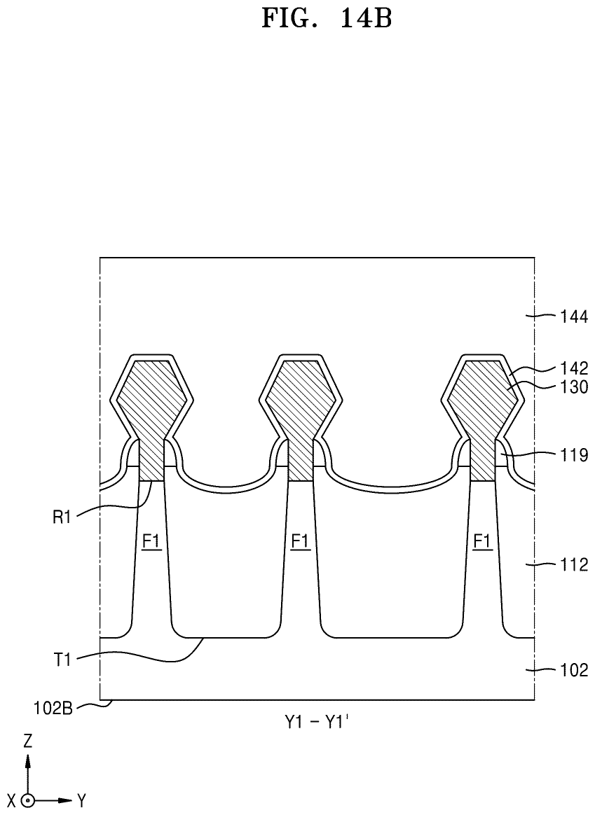

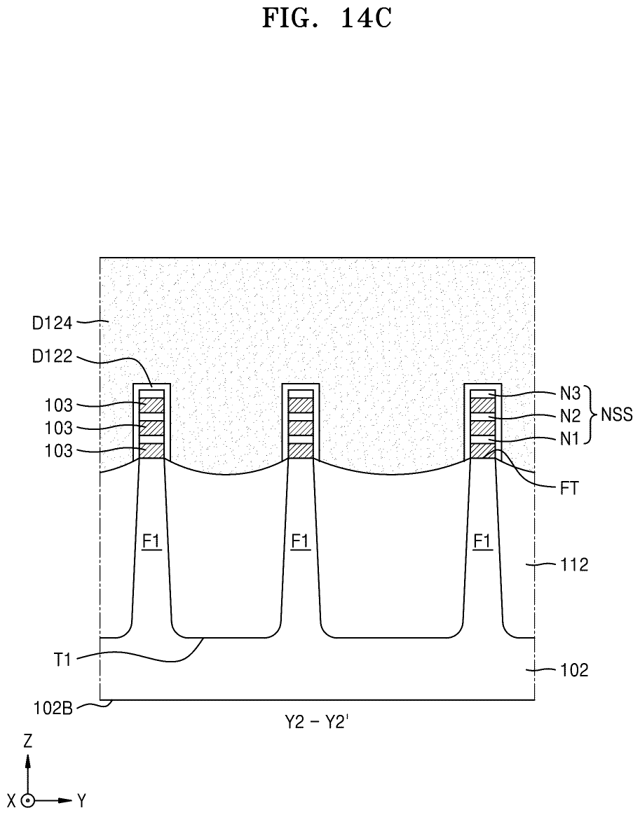

Referring to FIGS. 14A, 14B, and 14C, an insulating liner 142 covering a resulting structure of FIG. 13 may be formed, an inter-gate insulating layer 144 may be formed on the insulating liner 142, and then the insulating liner 142 and the inter-gate insulating layer 144 may be partially etched, and thereby, upper surfaces of the plurality of the capping layer D126 may be exposed. Thereafter, the plurality of the capping layer D126 may be removed to expose a dummy gate layer D124, and the insulating liner 142 and the inter-gate insulating layer 144 may be partially removed such that a level of an upper surface of the dummy gate layer D124 may be approximately the same as a level of an upper surface of the inter-gate insulating layer 144.

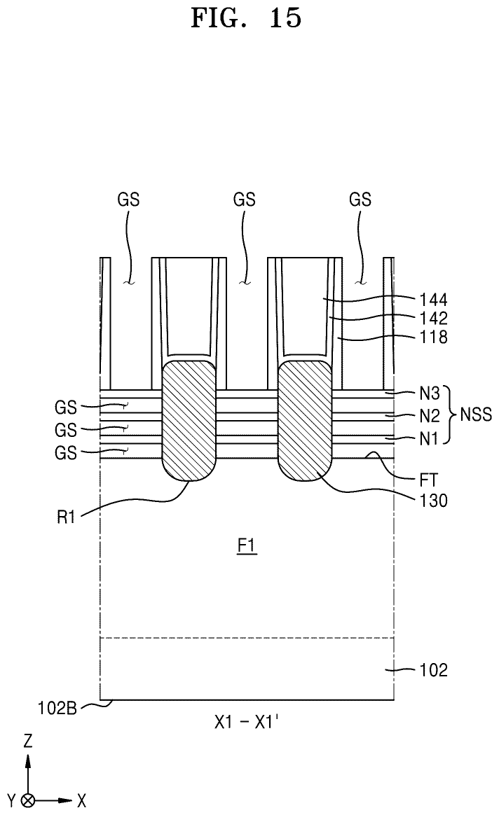

Referring to FIG. 15, the dummy gate layer D124 and the oxide film D122 thereunder may be removed from a resulting structure of FIGS. 14A, 14B, and 14C to form gate spaces GS, and the plurality of nanosheet stacks NSS may be exposed by the gate spaces GS. Thereafter, a plurality of sacrificial semiconductor layers 103 remaining on the fin-type active region F1 may be removed through the gate spaces GS, and thereby, the gate spaces GS may extend to spaces between the first nanosheet N1, the second nanosheet N2, and the third nanosheets N3, and a space between the first nanosheet N1 and the upper surface FT. In embodiments, in order to selectively remove the plurality of sacrificial semiconductor layers 103, a difference between selection ratios of the first nanosheet N1, the second nanosheet N2, the third nanosheet N3, and the plurality of sacrificial semiconductor layers 103 may be used.

A liquid or vapor phase etchant may be used to selectively remove the plurality of sacrificial semiconductor layers 103. In embodiments, a CH3COOH-based etchant, such as an etchant consisting of a mixture of CH3COOH, HNO3, and HF, or an etchant consisting of a mixture of CH3COOH, H2O2, and HF may be used to selectively remove the plurality of sacrificial semiconductor layers 103 but is not limited thereto.

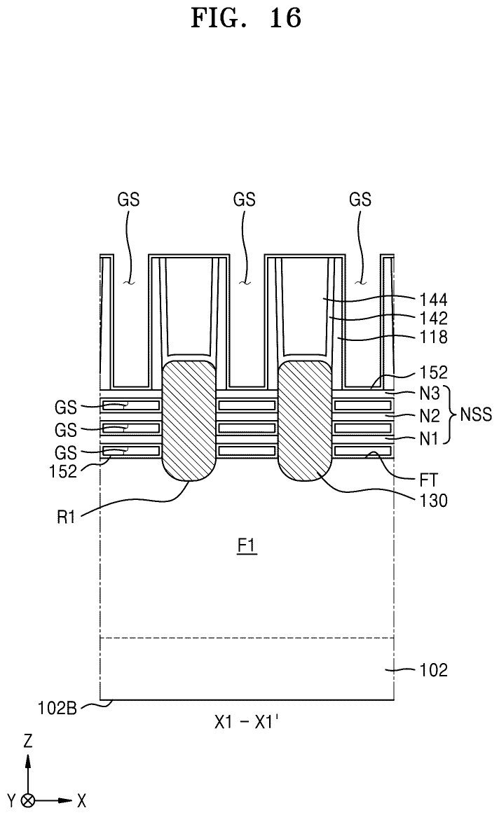

Referring to FIG. 16, a gate dielectric layer 152 that covers an exposed surface of each of the first nanosheet N1, the second nanosheet N2, the third nanosheet N3, and at least one of the fin-type active regions F1 may be formed in a resulting structure of FIG. 15. An atomic layer deposition (ALD) process may be used to form the gate dielectric layer 152.

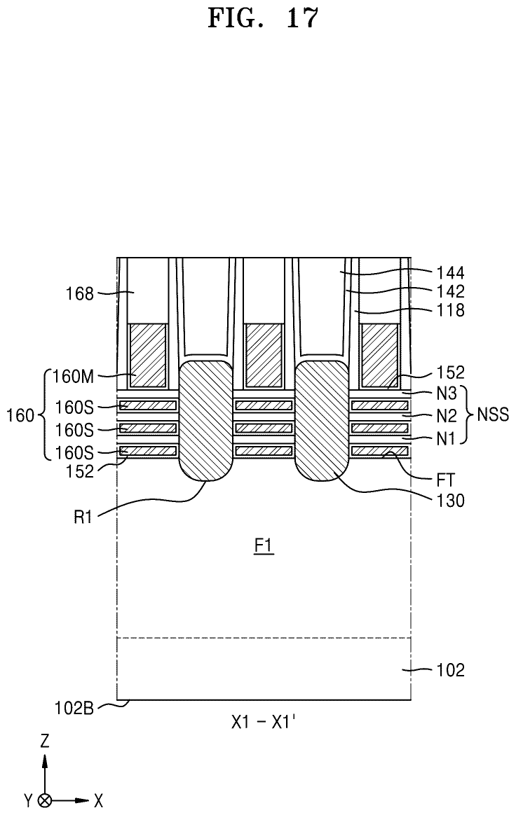

Referring to FIG. 17, a gate line 160 that fills the gate space GS (see FIG. 17) on the gate dielectric layer 152 and covers an upper surface of the inter-gate insulating layer 144, and a capping insulating pattern 168 that covers upper surfaces of the gate line 160 and the gate dielectric layer 152 on the gate space GS may be formed.

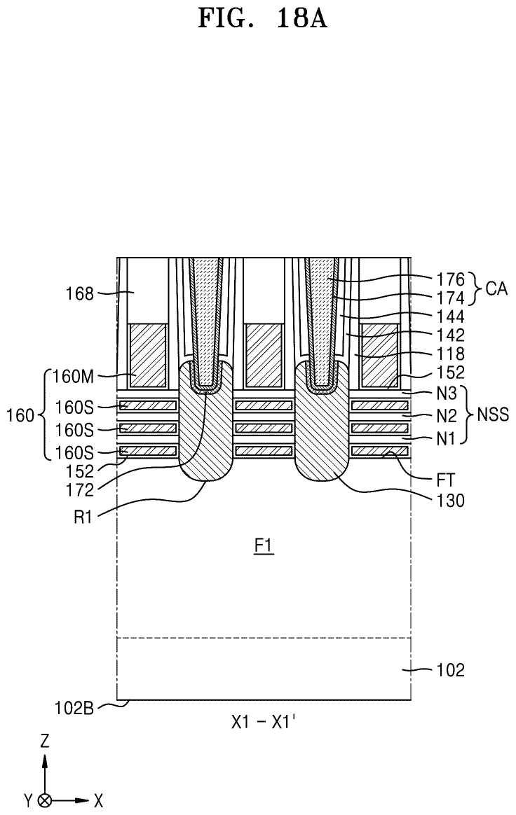

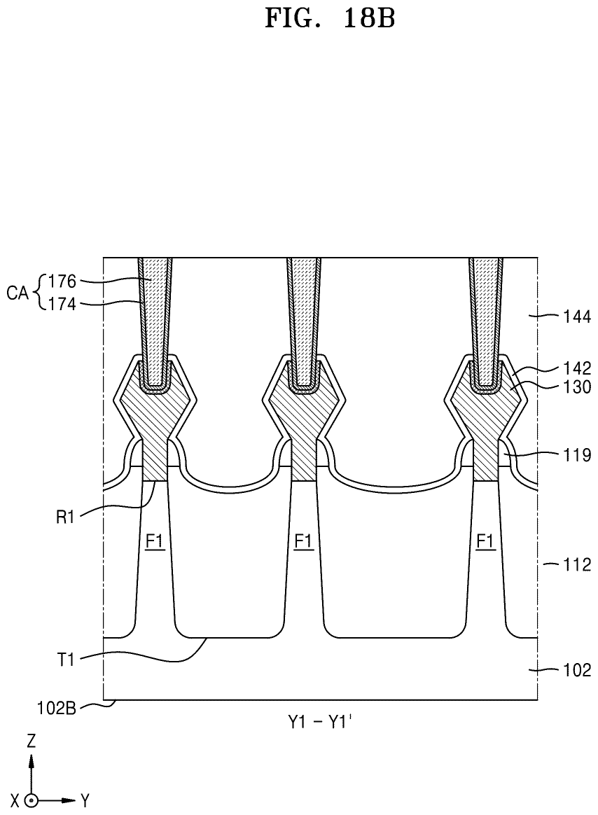

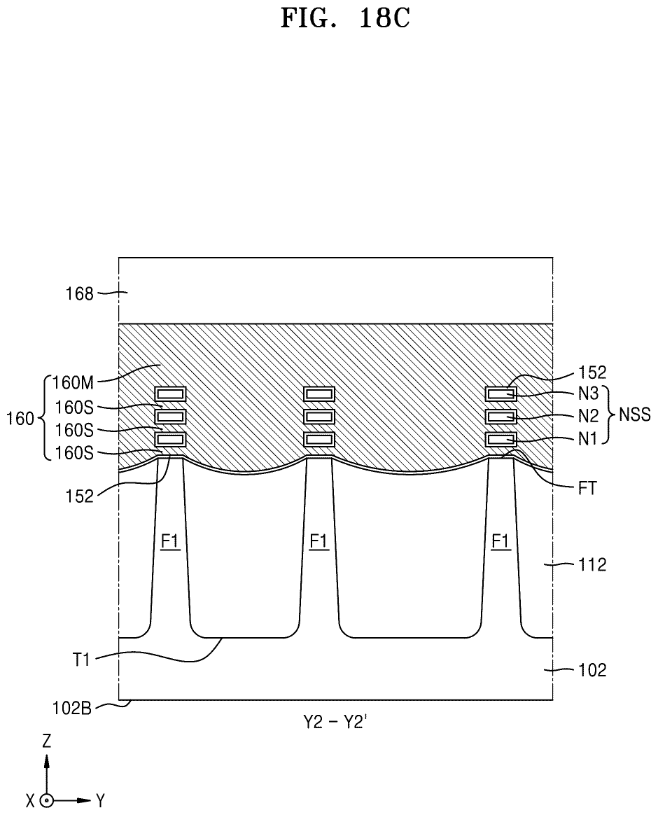

Referring to FIGS. 18A, 18B, and 18C, a source/drain contact hole that passes through an insulating structure including the insulating liner 142 and the inter-gate insulating layer 144 to exposes at least one of the source/drain regions 130 may be formed in a resulting structure of FIG. 17, and then part of the at least one of the source/drain regions 130 may be removed through the source/drain contact hole by an anisotropic etching process, and thereby, the source/drain contact hole may be further extended toward the substrate 102. Thereafter, a metal silicide layer 172 may be formed on the at least one of the source/drain regions 130 exposed at a bottom side of the source/drain contact hole. In embodiments, a process of forming a metal liner conformally covering the exposed surface of the at least one of the source/drain regions 130 and heat-treating the metal liner to induce a reaction between the at least one of the source/drain regions 130 and the metal forming the metal liner may be performed to form the metal silicide layer 172. After the metal silicide layer 172 is formed, the remaining portion of the metal liner may be removed. During a process of forming the metal silicide layer 172, part of the at least one of the source/drain regions 130 may be consumed. In embodiments, when the metal silicide layer 172 includes a titanium silicide layer, the metal liner may include a Ti film.

Thereafter, a source/drain contact CA including a conductive barrier pattern 174 and a contact plug 176 may be formed on the metal silicide layer 172.

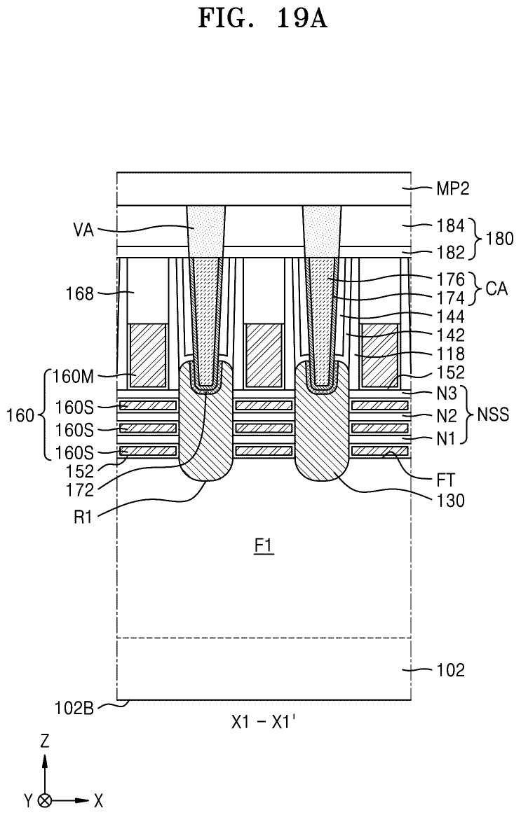

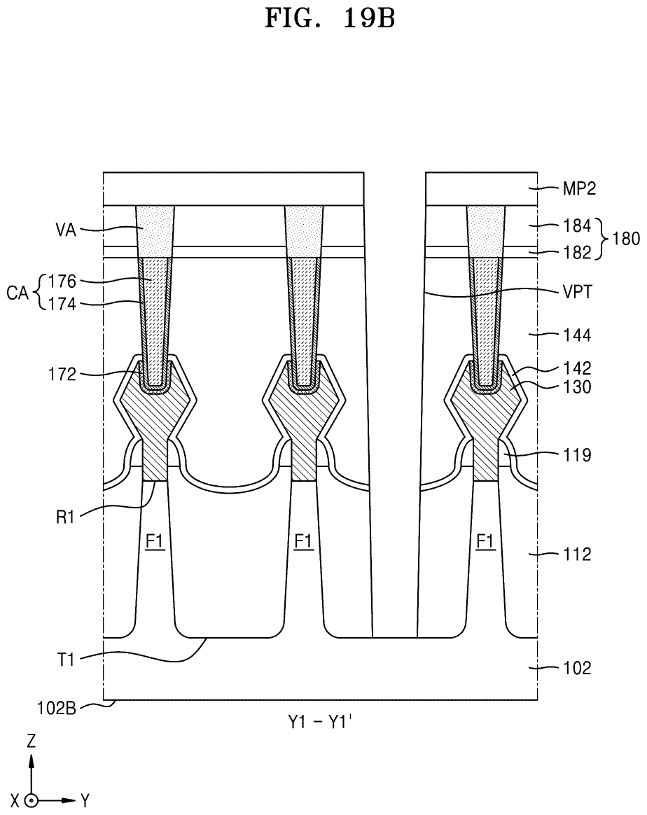

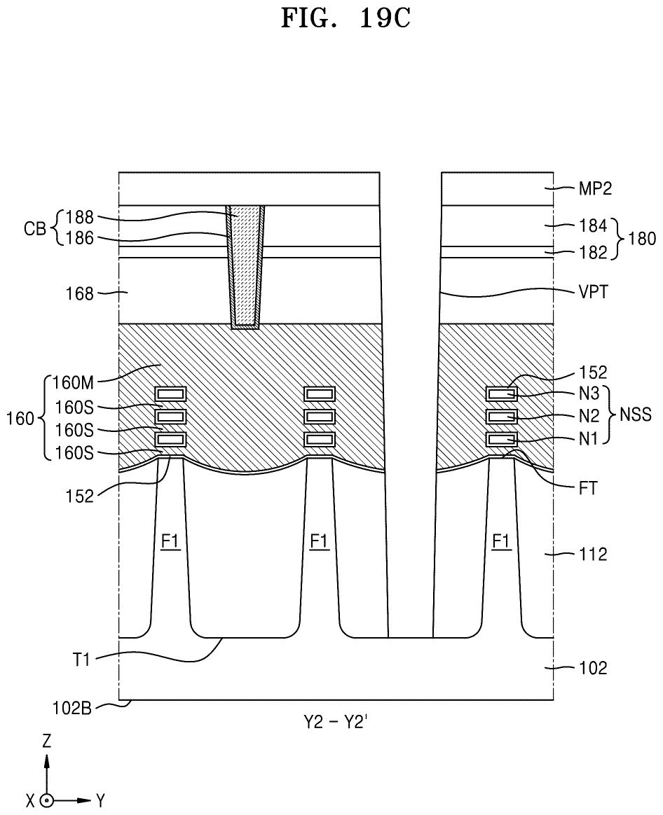

Referring to FIGS. 19A, 19B, and 19C, an upper insulating structure 180 may be formed by sequentially forming an etch stop layer 182 and an interlayer insulating layer 184 that cover upper surfaces of an inter-gate insulating layer 144, a plurality of source/drain contacts CA, and a plurality of capping insulating patterns 168 in a resulting structure of FIGS. 19A, 19B, and 19C.

Thereafter, a plurality of source/drain via contacts VA extending through the upper insulating structure 180 in the vertical direction Z to be connected to the plurality of source/drain contacts CA, a gate contact CB extending through the upper insulating structure 180 and the capping insulating pattern 168 in the vertical direction Z to be is connected to at least one of the gate lines 160, and a via power trench VPT may be formed. Although a formation sequence of the source/drain via contacts VA, the gate contact CB, and the via power trench VPT is not limited in particular, description is made hereinafter by assuming that the source/drain via contacts VA and the gate contact CB are formed earlier than the via power trench VPT.

In order to form the via power trench VPT, a mask pattern MP2 may be formed on a structure of FIGS. 18A, 18B, and 18C, and then the upper insulating structure 180, the inter-gate insulating layer 144, the insulating liner 142, the gate line 160, the gate dielectric layer 152, and the device isolation layer 112 may be partially etched by using the mask pattern MP2 as an etch barrier. Through an etching process, a via power trench VPT penetrating the upper insulating structure 180, the inter-gate insulating layer 144, the insulating liner 142, the gate line 160, the gate dielectric layer 152, and the device isolation layer 112 in the vertical direction Z may be formed. In embodiments, a dry etching process may be used to form the via power trench VPT. In this case, part of an upper surface of the substrate 102 may be exposed by the bottom of the via power trench VPT.

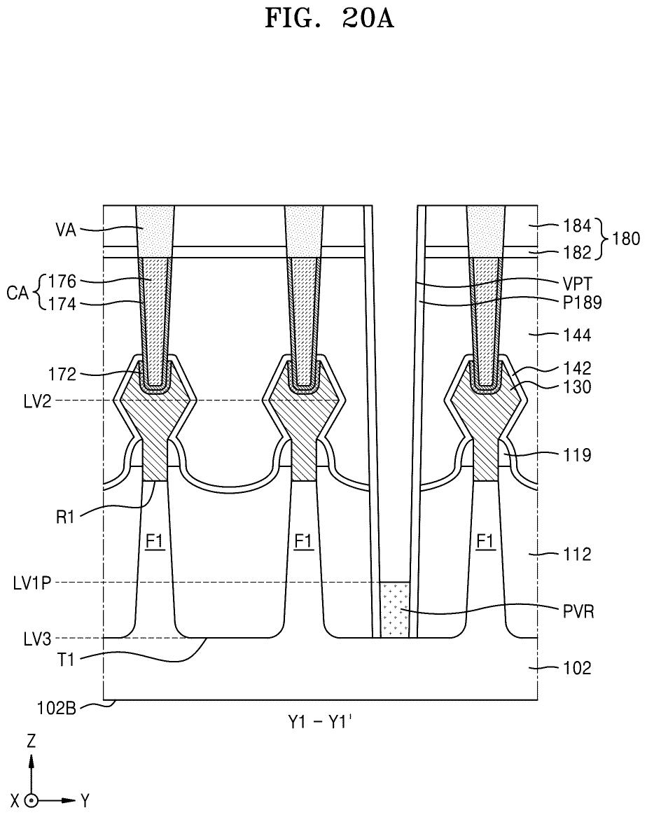

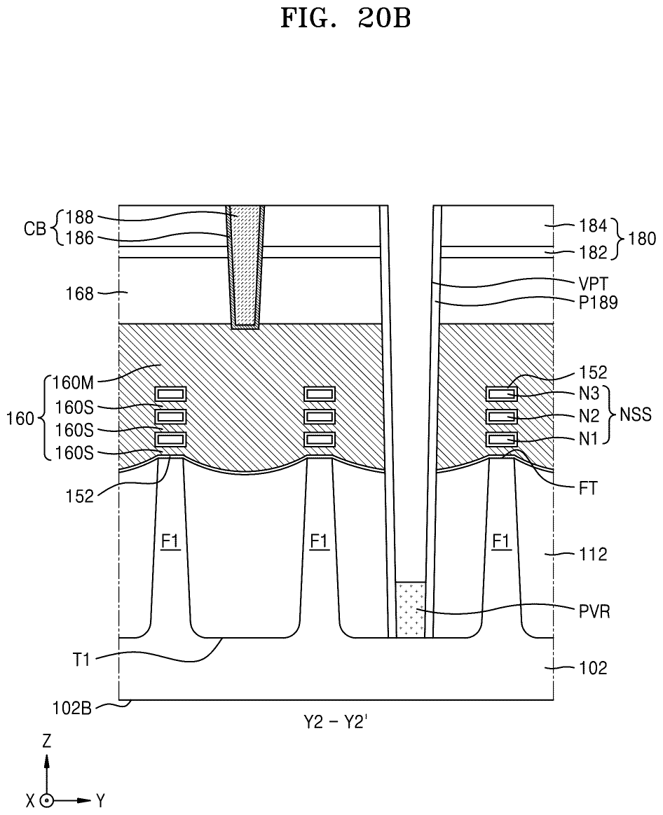

Referring to FIGS. 20A and 20B, in order to remove the mask pattern MP2 of FIGS. 19A, 19B, and 19C, an ashing process may be performed to remove the mask pattern MP2 by using plasma including oxygen groups or oxygen ions. Thereafter, in order to remove the remaining mask pattern or remaining impurities, a result structure of the ashing process may be cleaned.

Thereafter, a preliminary insulating spacer P189 extending along a side wall of the via power trench VPT may be formed. For example, the preliminary insulating spacer P189 may include a silicon oxide film, a silicon oxynitride film, or a combination thereof. The preliminary insulation spacer P189 may be deposited through various methods, such as plasma enhanced chemical vapor deposition (PECVD), high density plasma CVD (HDP CVD), inductively coupled plasma CVD (ICP CVD), capacitor coupled plasma CVD (CCP CVD), and flowable chemical vapor deposition (FCVD), and a spin coating process.

A preliminary via power rail PVR may be formed below the via power trench VPT in which the preliminary insulating spacer P189 is formed. In embodiments, the preliminary via power rail PVR may include a metal layer which may include, for example, Ru, Co, W, Mo, Cu, Rh, Ir, Ti, or a combination thereof. The metal layer may be deposited by using various processes, for example, a CVD process, such as PECVD, thermal CVD, atmospheric pressure chemical vapor deposition (APCVD), low pressure chemical vapor deposition (LPCVD), an ALD process, and so on.

In embodiments, the metal layer may be selectively deposited on an upper surface of the substrate 102 exposed by the via power trench VPT compared to a side wall of the preliminary insulating spacer P189. For example, when the metal layer includes Mo, the metal layer may be deposited by using MoCl5 or MoO2Cl2 as a precursor. When MoCl5 or MoO2Cl2 is used as a precursor, MoCl5 or MoO2Cl2 is deposited better on Si than on a silicon oxide film, and accordingly, the metal layer may be grown on an upper surface of the substrate 102 exposed by the via power trench VPT. In this case, when heat is used in the metal layer deposition process, a silicide layer including the same metal as the metal layer may also be formed on the upper surface of the substrate 102 connected to the metal layer.

In this case, a vertical level LVIP of an upper surface of the preliminary via power rail PVR may be between a vertical level LV2 of a portion of the pair of the source/drain regions 130, that are adjacent to the via power trench VPT, closest to the via power trench VPT, and a vertical level LV3 of an upper surface of the backside power rail BPW.

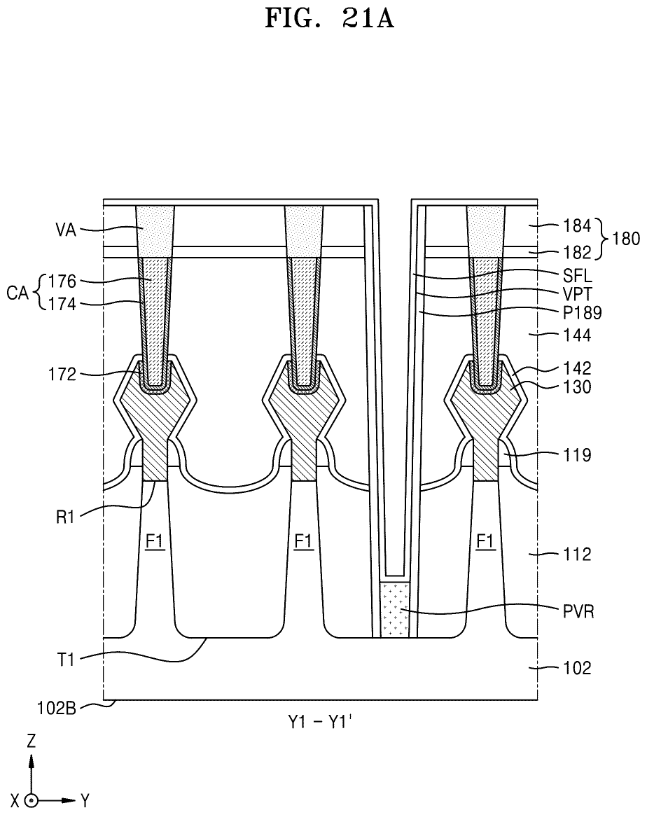

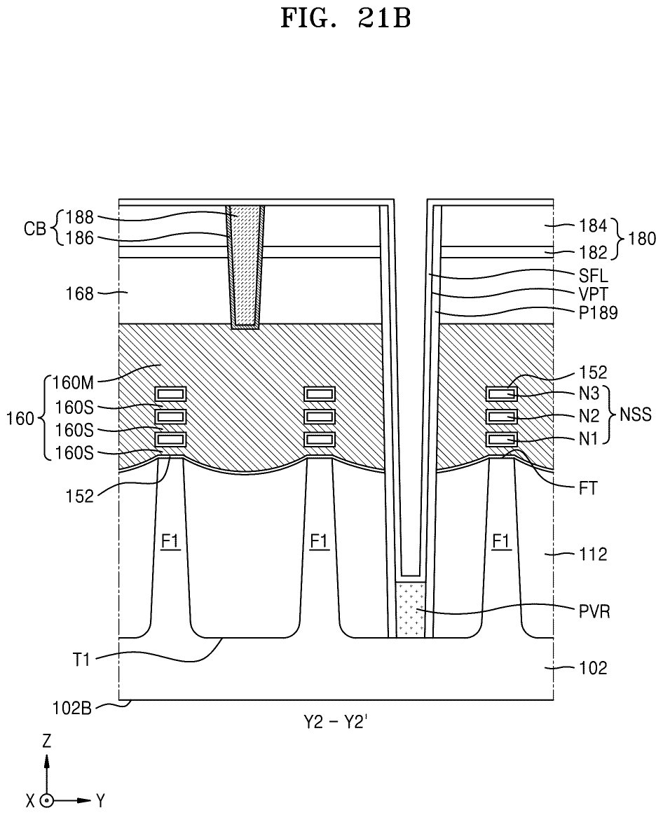

Referring to FIGS. 21A and 21B, a sacrificial insulating liner SFL may be formed on a resulting structure of FIGS. 20A and 20B. The sacrificial insulating liner SFL may cover upper surfaces of the plurality of source/drain via contacts VA, an upper surface of the upper insulating structure 180, an upper surface and side wall of the preliminary insulating spacer P189, and an upper surface of the preliminary via power rail PVR. The sacrificial insulation liner SFL may be conformally deposited on the upper surfaces of the plurality of source/drain via contacts VA, the upper surface of the upper insulating structure 180, the upper surface and side wall of the preliminary insulating spacer P189, and the upper surface of the preliminary via power rail PVR. In embodiments, the sacrificial insulating liner SFL may include a dielectric film, such as a silicon nitride film or a silicon oxide film, or a metal film that has a selection ratio with a metal layer forming the preliminary via power rail PVR.

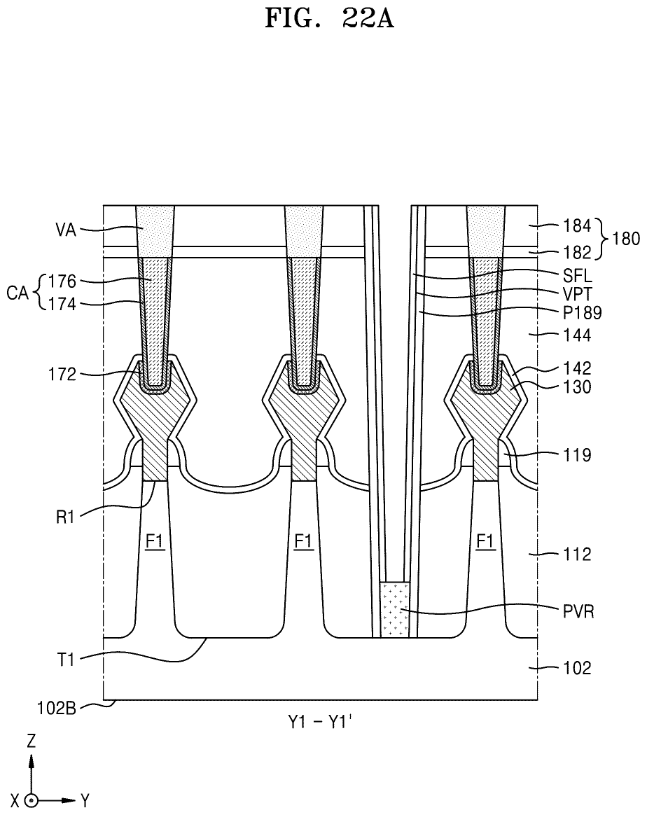

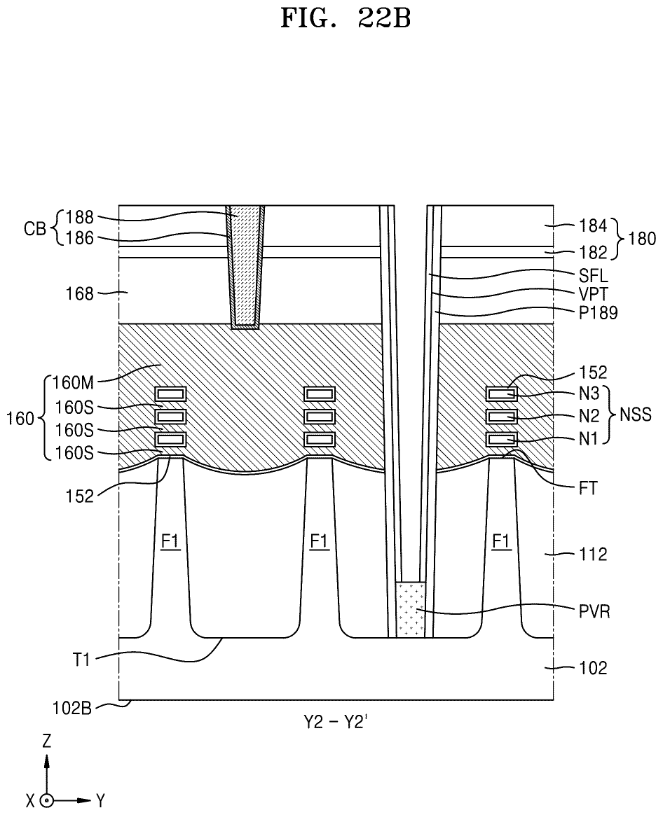

Referring to FIGS. 22A and 22B, an anisotropic etching process for removing part of the sacrificial insulating liner SFL to expose the upper surface of the preliminary via power rail PVR may be performed on a resulting structure of FIGS. 21A and 21B. In embodiments, a dry etching process, such as an RIE process, may be performed to remove a portion of the sacrificial insulating liner SFL which covers the upper surfaces of the plurality of source/drain via contacts VA, a portion of the sacrificial insulating liner SFL that covers the upper surface of the upper insulating structure 180, and a portion of the sacrificial insulating liner SFL that covers the upper surface of the prelminary via power rail PVR.

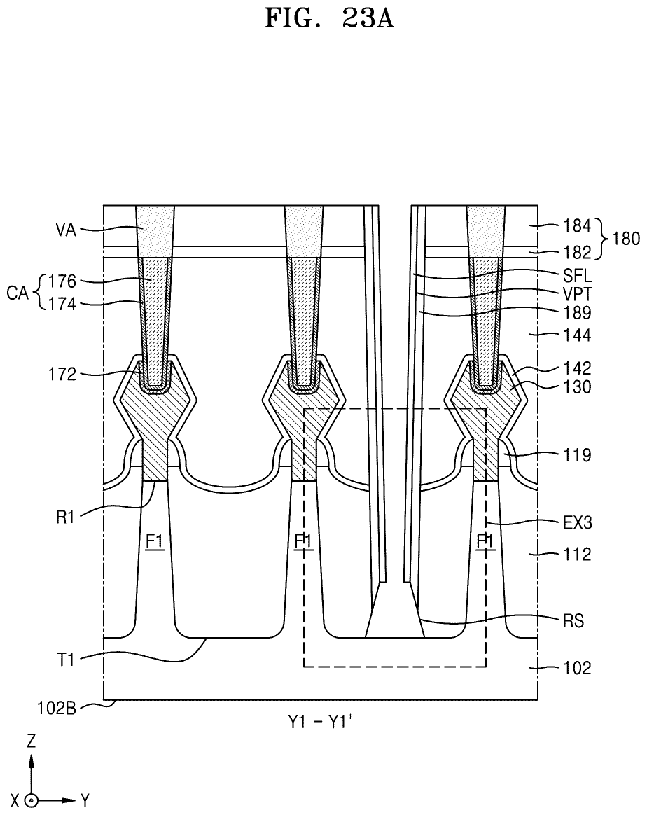

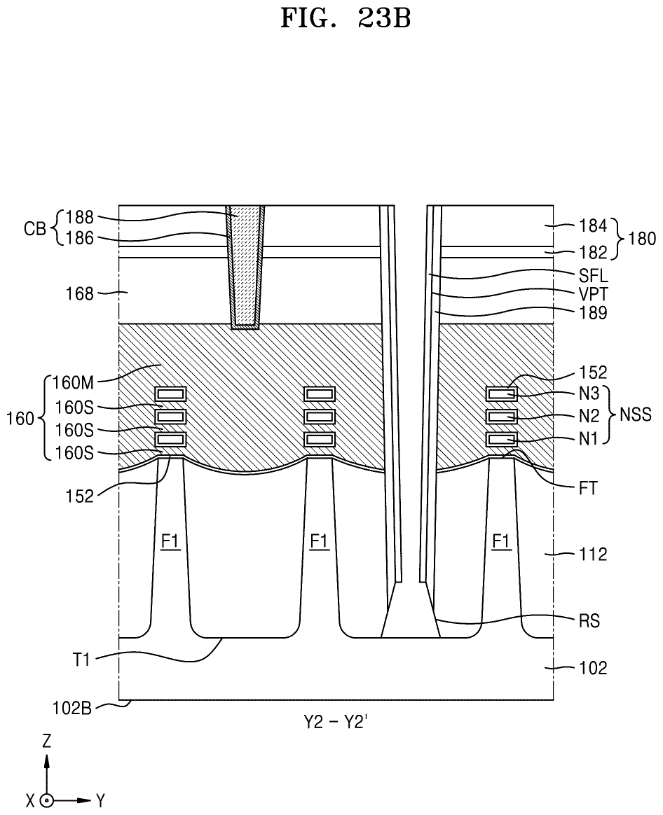

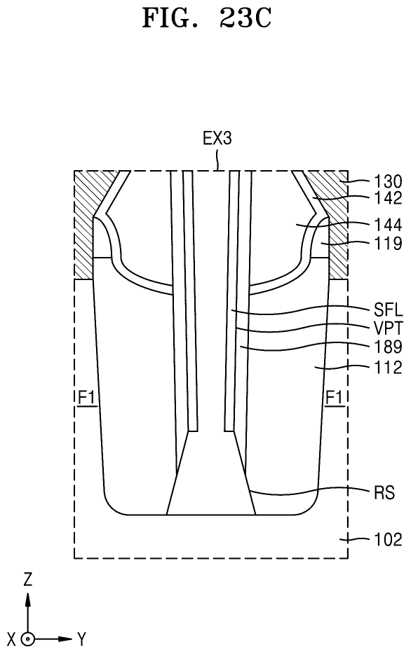

Referring to FIGS. 23A and 23B, a dry etching process, a wet etching process, or a combination thereof may be performed to selectively remove the preliminary via power rail PVR. For example, in order to selectively remove the preliminary via power rail PVR, a dry etching process, such as atomic layer etching (ALE) or a wet etching process, such as a sulfuric peroxide mixture (SPM) process using an SPM (Piranha) solution or an SC1 process using a cleaning solution mixed with ammonia, hydrogen peroxide and water in a certain ratio, may be performed.

Thereafter, the preliminary via power rail PVR may be removed, and thereby, part of the preliminary insulating spacer P189 that is not covered and exposed by the sacrificial insulating liner SFL may be exposed. Thereafter, part of the preliminary insulating spacer P189 that is not covered and exposed by the sacrificial insulating liner SFL may be removed, and part of the device isolation layer 112 exposed by removing part of the preliminary insulating spacer P189 may be removed to form a recess RS. In order to remove a part of the preliminary insulating spacer P189 and a part of the device isolation layer 112, anisotropic etching or isotropic etching may be performed. For example, a dry etching process, such as an RIE process, may be performed, and a wet etching process using a buffered oxide etch (BOE) solution including HF as an etchant may be performed.

In embodiments, when performing an anisotropic etching process, a side wall of the preliminary insulating spacer P189 and a side wall of the device isolation layer 112 exposed by removing a part of the preliminary insulating spacer P189 may be formed as inclined surfaces, and thereby, a lower portion of the preliminary insulating spacer P189 may be removed more than an upper portion of the preliminary insulating spacer P189, and a lower portion of the device isolation layer 112 may be removed more than an upper portion of the device isolation layer 112. Therefore, as illustrated in FIGS. 23A and 23B, the recess RS may be formed such that a width of a lower portion of the recess RS in the second horizontal direction Y is greater than a width of an upper portion the recess RS in the second horizontal direction Y. By adjusting the amount of removal of part of the preliminary insulating spacer P189 and a part of the device isolation layer 112, the recess RS may have the shape illustrated in FIGS. 23A and 23B, or the recess RS may have the same shape as the shape of the first portion LVR2 of the via power rail VPR2 illustrated in FIG. 4.

In other embodiments, when performing an isotropic etching process, upper, lower, and middle portions of the preliminary insulating spacer P189 may be similarly removed, and upper, lower, and middle portions of the device isolation layer 112 may be similarly removed. Accordingly, when an isotropic etching process is performed, the recess RS may have the same shape as the first portion LVR3 of the via power rail VPR3 illustrated in FIGS. 5A and 5B.

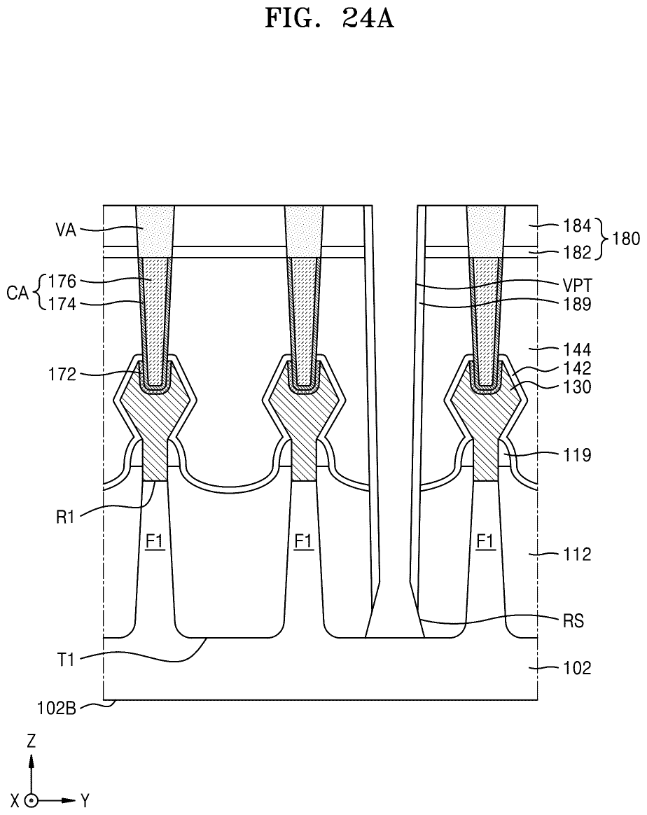

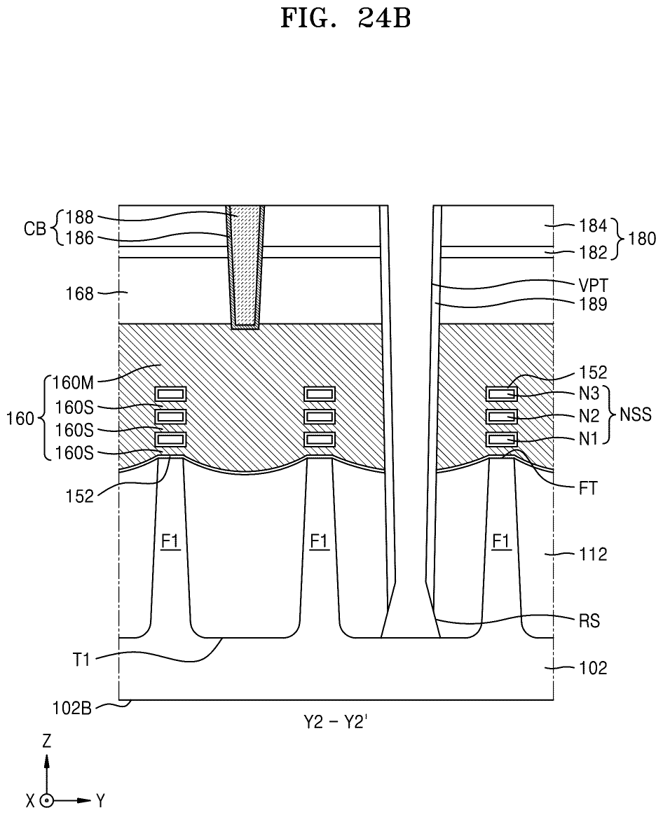

Referring to FIGS. 24A and 24B, a dry etching process or a wet etching process may be performed to selectively remove the sacrificial insulating liner SFL from a resulting structure of FIGS. 23A and 23B. For example, a dry etching process may be performed by using hydrogen radicals and fluorine radicals, or a wet etching process may be performed by using a solution including phosphoric acid (H3PO4) as an etchant.

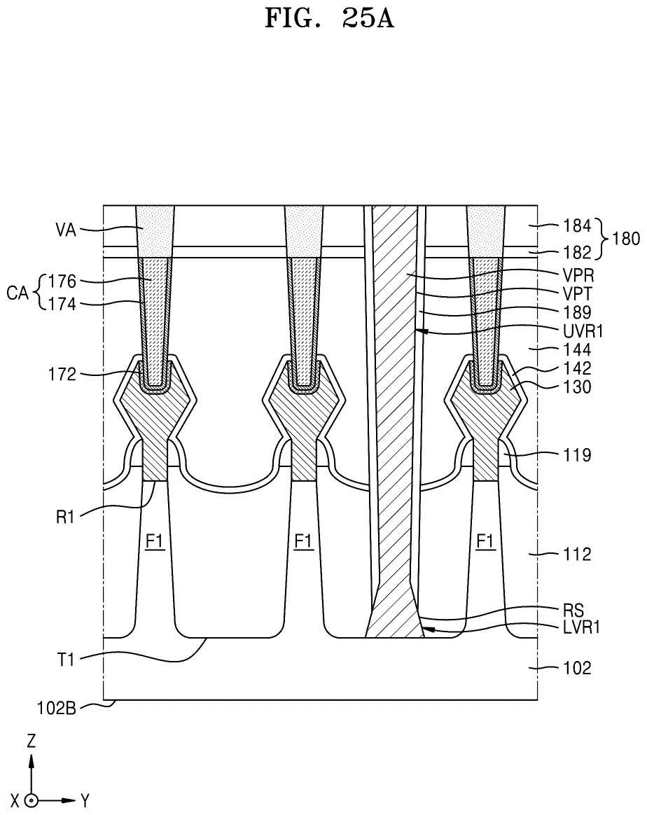

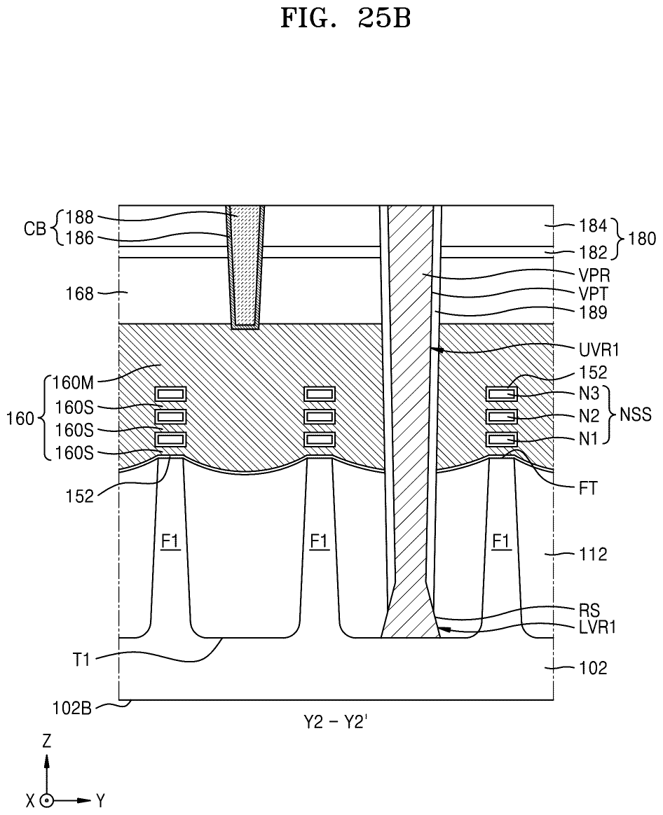

Referring to FIGS. 25A and 25B, a via power rail VPR may be formed on a resulting structure of FIGS. 24A and 24B. The via power rail VPR may be formed by depositing a metal wiring layer inside the via power trench VPT and inside the recess RS. A deposition process of the metal wiring layer is similar to the deposition process of the metal layer forming the preliminary via power rail PVR. For example, the metal wiring layer may be deposited through various processes, for example, a CVD process, such as PECVD, thermal CVD, APCVD, or LPCVD, an ALD process, and so on.

In embodiments, the metal wiring layer may include a first metal, and the first metal may include, for example, Ru, Co, W, Mo, Cu, Rh, Ir, Ti, or a combination thereof. In one embodiment, when the first metal includes Mo, a deposition process of the metal wiring layer may be performed by a CVD process using MoO2Cl2 or MoCl5 as a precursor, or an ALD process. Thereafter, a chemical mechanical polishing process may be performed to planarize an upper surface of the metal wiring layer.

In embodiments, before the metal wiring layer is deposited, a process of cleaning impurities, such as a natural oxide film, inside the via power trench VPT and inside the recess RS, may be first performed to reduce resistance of the metal wiring layer for a resulting structure of FIGS. 24A and 24B.

As a result, the via power rail VPR may be formed as illustrated in FIGS. 25A and 25B. However, the process illustrated in FIGS. 25A and 25B is an example, and the via power rail VPR may be formed through various processes including the process illustrated in FIGS. 25A and 25B.

In another embodiment, as illustrated in FIG. 6, before the metal wiring layer forming the via power rail VPR is deposited, a conductive barrier layer 190a may be deposited inside the via power trench VPT and inside the recess RS. The conductive barrier layer 190a may be conformally deposited along an inner wall of the insulating spacer 189 and an inner wall of the recess RS. The conductive barrier layer 190a may include, for example, Ti, TiN, TaN, WN, WCN, TiSiN, TaSIN, WSiN, or a combination thereof but is not limited thereto.

In another embodiment, as illustrated in FIG. 7, before the metal wiring layer forming the via power rail VPR is deposited, the conductive barrier layer 190b may also be formed inside the via power trench VPT and inside the recess RS. For example, in order to form the conductive barrier layer 190b, a barrier layer may be conformally formed on an inner wall of the via power trench VPT and an inner wall of the recess RS. The barrier layer may include, for example, Ti, TiN, TaN, WN, WCN, TiSiN, TaSiN, WSiN, or a combination thereof but is not limited thereto. Thereafter, an upper portion of the barrier layer may be removed through an etch-back process and so on, and the conductive barrier layer 190b including the remaining barrier layer may be formed.

In another embodiment, as illustrated in FIG. 8, before a metal wiring layer forming the via power rail VPR is deposited, the metal wiring silicide layer 186 may also be formed on an upper surface of the substrate 102 exposed by the bottom of the via power trench VPT. For example, in order to form the metal wiring silicide layer 186, a preliminary metal wiring layer including a first metal may be deposited on the upper surface of the substrate 102 exposed by the bottom of the via power trench VPT. The first metal is similar to the first metal described for the via power rail VPR. Thereafter, heat may be applied to the preliminary metal wiring layer to form the metal wiring silicide layer 186.

In another embodiment, as illustrated in FIG. 9, before the metal wiring layer forming the via power rail VPR is deposited, the metal wiring silicide layer 186 may be formed on an upper surface of the substrate 102 exposed by the bottom of the via power trench VPT, and the connection metal layer 188 may be further formed on the metal wiring silicide layer 186. In order to form the metal wiring silicide layer 186, a preliminary metal wiring layer including a first metal may be deposited on the upper surface of the substrate 102 exposed by the bottom of the via power trench VPT. The first metal is similar to the first metal described for the via power rail VPR. Thereafter, heat may be applied to the preliminary metal wiring layer to form the metal wiring silicide layer 186. The connection metal layer 188 may be formed by depositing a metal layer including a second metal different from the first metal. For example, the connection metal layer 188 may be formed through an ALD process.

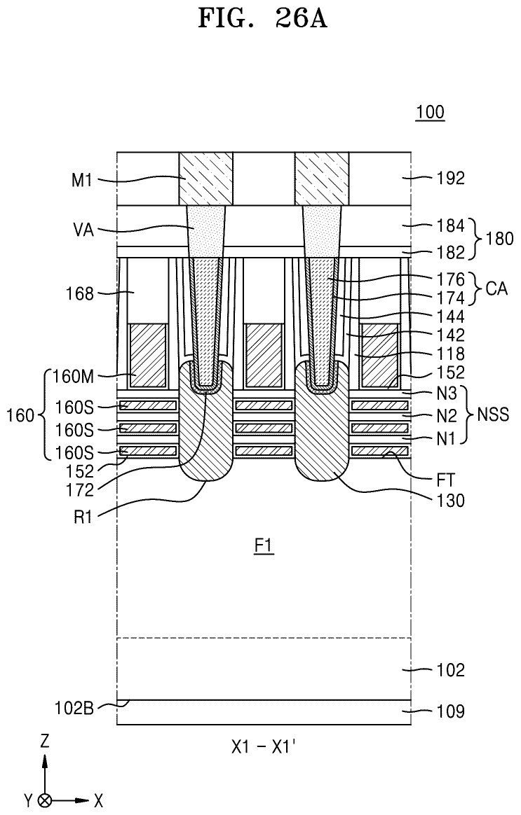

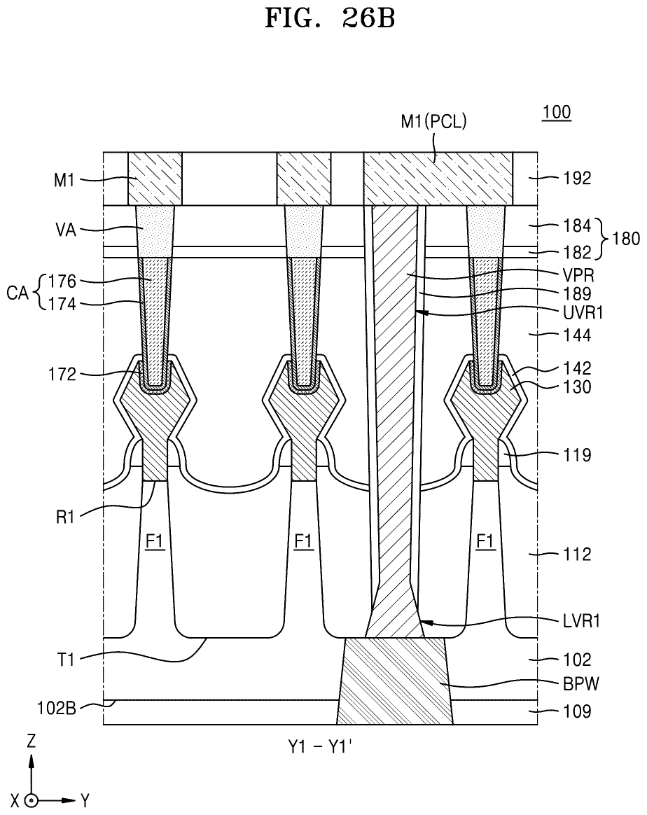

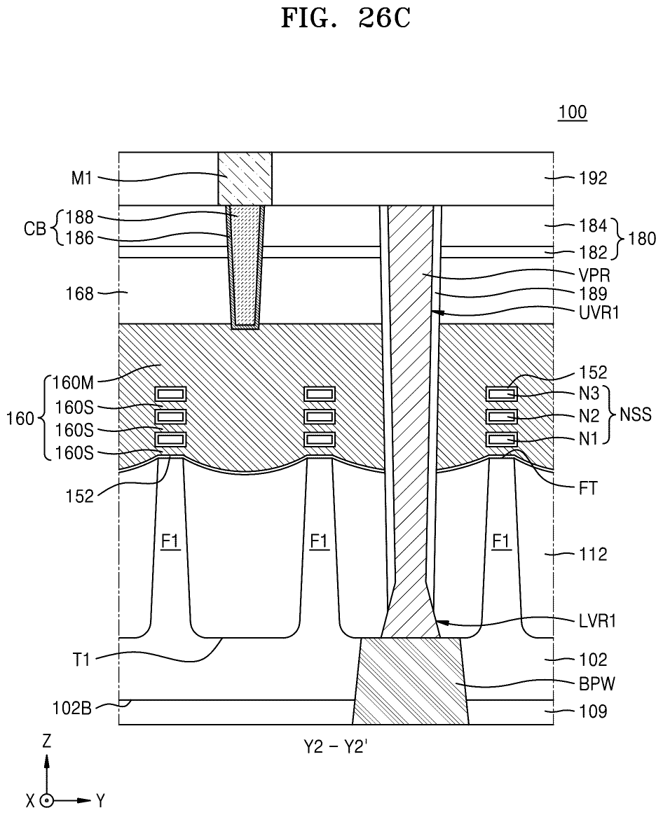

Referring to FIGS. 26A, 26B, and 26C, an upper insulating layer 192 covering the upper insulating structure 180, and a plurality of upper wiring layers M1 extending through the upper insulating layer 192 to be connected to the source/drain via contacts VA, the gate contact sCB, and the via power rail VPR may be formed in a resulting structure of FIGS. 25A and 25B. The plurality of upper wiring layers M1 may include a power connection conductive layer PCL connected to the via power rail VPR on the via power rail VPR.

A backside insulating layer 109 may be formed to cover the backside surface 102B of the substrate 102, and a backside power rail BPW extending through the backside insulating layer 109 and the substrate 102 in the vertical direction Z to be connected to one end of the via power rail VPR may be formed.

According to embodiments, a process of forming the recess RS is included to form the power rail VPR, and accordingly, the via power rail VPR having a relatively large contact area with the backside power rail BPW may be formed. As a result, an integrated circuit device with a reduced electrical resistance between the backside power rail BPW and the via power rail VPR and increased reliability and electrical characteristics may be provided.

As described above, non-limiting example embodiments are described in the present disclosure and illustrated in the drawings. In the present disclosure, non-limiting example embodiments are described by using certain terms, but these terms are only used for the purpose of describing examples and are not used to limit the meaning or scope of the present disclosure. Therefore, those skilled in the art will understand that various modifications and other equivalent embodiments may be derived therefrom.

While the present disclosure has been particularly shown and described with reference to non-limiting example embodiments thereof, it will be understood that various changes in form and details may be made therein without departing from the spirit and scope of the present disclosure.

What is claimed is:

1. An integrated circuit device comprising:
a substrate comprising a backside surface;
a pair of fin-type active regions protruding from the substrate such as to define a trench region on the substrate on a side of the substrate that is opposite of the backside surface;
a device isolation layer covering, in the trench region, a side wall of each of the pair of fin-type active regions;
a via power rail vertically extending through the device isolation layer between the pair of fin-type active regions; and
a backside power rail vertically extending through the substrate from the backside surface of the substrate and connected to one end of the via power rail,
wherein the via power rail comprises a first portion connected to the backside power rail and a second portion on the first portion, and
wherein two side walls of the first portion, that are opposite of each other and respectively face the pair of fin-type active regions, each comprise an inclined surface that is inclined such as to come closer to the pair of fin-type active regions as the two side walls approach the backside power rail.

2. The integrated circuit device of claim 1, wherein two side walls of the second portion, that are opposite of each other and face the pair of fin-type active regions, each comprise an inclined surface that is inclined such as to become farther away from the pair of fin-type active regions as the two side walls approach the first portion.

3. The integrated circuit device of claim 1, wherein
an upper surface of the first portion connects the two side walls of the first portion to the two side walls of the second portion.

4. The integrated circuit device of claim 1, wherein the two side walls of the first portion are directly connected to the two side walls of the second portion.

5. The integrated circuit device of claim 1, further comprising a conductive barrier layer comprising a portion between the via power rail and the backside power rail.

6. The integrated circuit device of claim 1, further comprising a conductive barrier layer covering the two side walls of the first portion, partially covering two side walls of the second portion, and covering a lower surface of the via power rail.

7. The integrated circuit device of claim 1, further comprising a conductive barrier layer covering the two side walls of the first portion, two sidewalls of the second portion, and a lower surface of the via power rail.

8. The integrated circuit device of claim 1, wherein
the via power rail comprises a metal wiring layer, and
the metal wiring layer comprises any one from among Ru, Co, W, Mo, Cu, Rh, Ir, and Ti.

9. The integrated circuit device of claim 1, further comprising a metal wiring silicide layer between the via power rail and the backside power rail.

10. The integrated circuit device of claim 1, further comprising:
a metal wiring silicide layer between the via power rail and the backside power rail; and
a connection metal layer between the via power rail and the metal wiring silicide layer.

11. The integrated circuit device of claim 1, further comprising:
an insulating spacer covering a part of a side wall of the via power rail,
wherein the first portion is directly connected to the device isolation layer, and
the second portion is separated from the device isolation layer with the insulating spacer therebetween.

12. The integrated circuit device of claim 1, wherein
a horizontal width of the first portion increases from an upper end of the first portion toward a lower end of the first portion, and
a horizontal width of the second portion decreases from an upper end of the second portion toward a lower end of the second portion.

13. An integrated circuit device comprising:
a substrate comprising a backside surface;
a pair of fin-type active regions protruding from the substrate such as to define a trench region on the substrate on a side of the substrate that is opposite of the backside surface;
a pair of source/drain regions respectively over the pair of fin-type active regions;
a device isolation layer covering, in the trench region, a side wall of each of the pair of fin-type active regions;
a via power rail between the pair of fin-type active regions and between the pair of source/drain regions and vertically extending through the device isolation layer; and
a backside power rail vertically extending through the substrate from the backside surface of the substrate and connected to one end of the via power rail,
wherein the via power rail comprises a first portion connected to the backside power rail and a second portion on the first portion, and
wherein two side walls of the first portion respectively face the pair of fin-type active regions and are curved surfaces.

14. The integrated circuit device of claim 13, wherein two side walls of the second portion respectively face the pair of fin-type active regions and are planar.

15. The integrated circuit device of claim 13, wherein the two side walls of the first portion each have a convex shape toward a respective one of the pair of fin-type active regions to which the convex shape faces.

16. The integrated circuit device of claim 13, wherein a cross-sectional area of a lowermost portion of the first portion that is connected to the backside power rail is greater than a cross-sectional area of an uppermost portion of the first portion that is connected to the second portion.

17. An integrated circuit device comprising:
a substrate comprising a backside surface;
a fin-type active region protruding from the substrate, on a side of the substrate that is opposite of the backside surface, such as to define part of a trench region on the substrate, the fin-type active region elongated in a first horizontal direction;
at least one nanosheet on the fin-type active region and separated vertically from an upper surface of the fin-type active region;
a gate line surrounding the at least one nanosheet on the fin-type active region, the gate line elongated in a second horizontal direction intersecting the first horizontal direction;
a source/drain region adjacent to the gate line and on the fin-type active region, the source/drain region connected to the at least one nanosheet;
a device isolation layer on the substrate and covering, in the trench region, a part of a side wall of the fin-type active region;
a via power rail separated horizontally from each of the fin-type active region, the source/drain region, and the gate line and vertically extending through the device isolation layer and the gate line; and
a backside power rail vertically extending through the substrate from the backside surface of the substrate and connected to one end of the via power rail,
wherein the via power rail comprises a first portion connected to the backside power rail and a second portion on the first portion,
wherein the first portion comprises at least a portion having a width in the second horizontal direction that increases toward the backside surface, and
wherein the second portion has a width in the second horizontal direction that decreases toward the backside surface.

18. The integrated circuit device of claim 17, wherein a vertical level of where the first portion connects to the second portion is between a vertical level of a portion of the fin-type active region closest to the via power rail and a vertical level of an upper surface of the backside power rail.

19. The integrated circuit device of claim 17, wherein the width of the first portion in the second horizontal direction increases from an upper portion of the first portion to a lower portion of the first portion that is connected to the backside surface.

20. The integrated circuit device of claim 17, wherein the width of the first portion in the second horizontal direction increases and then decreases from an upper portion of the first portion to a lower portion of the first portion that is connected to the backside surface.
